(19) United States
(12) Patent Application Publication
(10) Pub. No.: US 2024/0147839 A1
(43) Pub. Date: May 2, 2024

(54) LIGHT-EMITTING ELEMENT AND PRODUCTION METHOD THEREFOR

(71) Applicant: SHARP KABUSHIKI KAISHA, Sakai City, Osaka (JP)

(72) Inventor: Yuma YAGUCHI, Sakai City, Osaka (JP)

(21) Appl. No.: 18/280,460

(22) PCT Filed: Mar. 9, 2021
(86) PCT No.: PCT/JP2021/009199

§ 371 Date: Sep. 5, 2023

(51) Int. Cl. H10K 85/30; C09K 11/02

(52) U.S. Cl. CPC H10K 85/381; C09K 11/02; B82Y 20/00

(57) ABSTRACT

A light-emitting element includes, between an anode electrode and a cathode electrode, a first nanoparticle layer including first nanoparticles and a second nanoparticle layer disposed to be in contact with the first nanoparticle layer and including second nanoparticles, and includes at an interface between the first nanoparticle layer and the second nanoparticle layer, a ligand including a first coordinating functional group for coordinating to the first nanoparticles and a second coordinating functional group for coordinating to the second nanoparticles.

### TECHNICAL FIELD

The disclosure relates to a light-emitting element including two or more adjacent nanoparticle layers, and a manufacturing method therefor.

### BACKGROUND ART

In recent years, there have been proposed some light-emitting elements including two or more adjacent nanoparticle layers using nanoparticles such as quantum dots or inorganic nanoparticles for example.

For example, PTL 1 discloses a light-emitting element in which a quantum dot light-emitting layer containing quantum dots is provided on an electron transport layer or a positive hole transport layer containing inorganic oxide nanoparticles as inorganic nanoparticles having carrier transporting properties. The quantum dots are also referred to as semiconductor nanoparticles.

### CITATION LIST

### Patent Literature

PTL 1: JP 2019-157129 A

### Non Patent Literature

NPL 1: Yu-Ho Won and nine others, Highly efficient and stable InP/ZnSe/ZnS quantum dot light-emitting diodes, Nature Vol 575, Nov. 28, 2019, pp. 634 to 638

### SUMMARY

### Technical Problem

However, when voltage for driving the light-emitting element including two or more adjacent nanoparticle layers as described above is applied to the light-emitting element, electromigration occurs in which the nanoparticles move in the direction in which the voltage is applied. As a result, the interface between the adjacent nanoparticle layers may move, and the nanoparticles of the adjacent nanoparticle layers may be mixed with each other to form a mixed layer of the nanoparticles.

Such a mixed layer thus formed may affect the lifetime, reliability, and the like of the light-emitting element, or may even change the light-emission characteristics of the light-emitting element.

An aspect of the disclosure has been made in view of the above-described problem, and an object of the present disclosure is to provide a light-emitting element that can suppress electromigration in a light-emitting element including two or more adjacent nanoparticle layers, and a manufacturing method therefor.

### Solution to Problem

A light-emitting element according to an aspect of the disclosure for solving the problem described above includes: a first electrode; a second electrode; a first nanoparticle layer disposed between the first electrode and the second electrode and including first nanoparticles; and a second nanoparticle layer disposed between the second electrode and the first nanoparticle layer and being in contact with the first nanoparticle layer, the second nanoparticle layer including second nanoparticles, wherein an interface between the first nanoparticle layer and the second nanoparticle layer includes a ligand including a first coordinating functional group for coordination to the first nanoparticles and a second coordinating functional group for coordination to the second nanoparticles.

A light-emitting element manufacturing method according to an aspect of the disclosure for solving the above problem is a manufacturing method for the light-emitting element according to the aspect of the disclosure described above and includes: forming a first nanoparticle containing layer including the first nanoparticles, which is to be the first nanoparticle layer; forming, on the first nanoparticle containing layer, a second nanoparticle containing layer including the second nanoparticles, which is to be the second nanoparticle layer; and supplying, onto the second nanoparticle containing layer, a ligand solution including the ligand including the first coordinating functional group for coordination to the first nanoparticles and the second coordinating functional group for coordination to the second nanoparticles, after the formation of the second nanoparticle containing layer.

### Advantageous Effects of Disclosure

According to an aspect of the disclosure, the first nanoparticles and the second nanoparticles can be immobilized via the ligand at the interface between the first nanoparticle layer and the second nanoparticle layer. Thus, according to an aspect of the disclosure, it is possible to provide a light-emitting element that can suppress electromigration in a light-emitting element including two or more adjacent nanoparticle layers, and a manufacturing method therefor.

### BRIEF DESCRIPTION OF DRAWINGS

FIG. 1 is a cross-sectional view illustrating an example of an overall configuration of a light-emitting element according to a first embodiment in which a main portion of the light-emitting element is enlarged and schematically illustrated.

FIG. 2 is a flowchart illustrating an example of an overview of a manufacturing method for the light-emitting element according to the first embodiment.

FIG. 3 is a flowchart illustrating another example of an overview of the manufacturing method for the light-emitting element according to the first embodiment.

FIG. 4 is a cross-sectional view illustrating a ligand solution supplying process illustrated in FIG. 2 or FIG. 3.

FIG. 5 is a cross-sectional view schematically illustrating a layered body after the ligand solution supplying process illustrated in FIG. 2 or FIG. 3.

FIG. 6 is a flowchart illustrating a still another example of an overview of the manufacturing method for the light-emitting element according to the first embodiment.

FIG. 7 is a cross-sectional view illustrating an example of an overall configuration of a light-emitting element according to a second embodiment in which a main portion of the light-emitting element is enlarged and schematically illustrated.

FIG. 8 is a flowchart illustrating an example of an overview of a manufacturing method for the light-emitting element according to the second embodiment.

FIG. 9 is a cross-sectional view illustrating an example of an overall configuration of a light-emitting element according to a third embodiment in which a main portion of the light-emitting element is enlarged and schematically illustrated.

FIG. 10 is a flowchart illustrating an example of an overview of a manufacturing method for the light-emitting element according to the third embodiment.

FIG. 11 is a cross-sectional view illustrating an example of an overall configuration of a light-emitting element according to a fourth embodiment in which a main portion of the light-emitting element is enlarged and schematically illustrated.

FIG. 12 is a flowchart illustrating an example of an overview of a manufacturing method for the light-emitting element according to the fourth embodiment.

### DESCRIPTION OF EMBODIMENTS

### First Embodiment

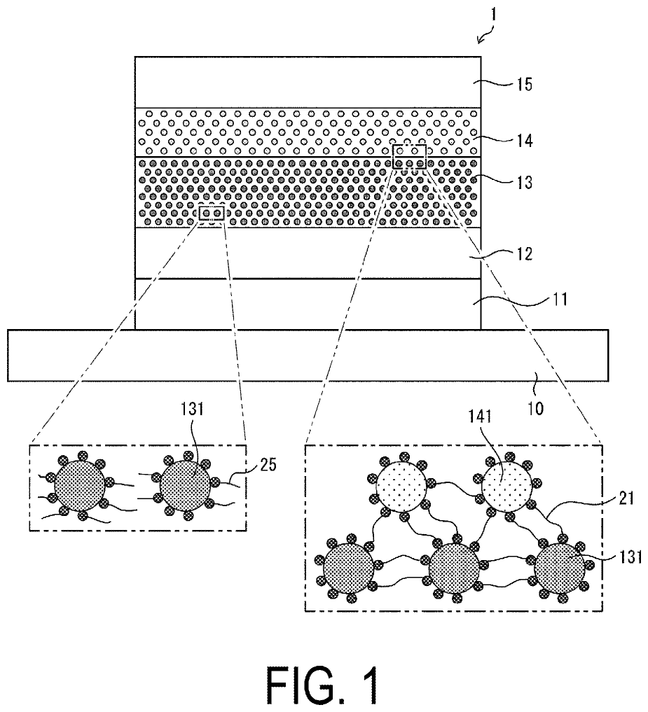

An embodiment of the disclosure will be described as follows based on FIGS. 1 to 6. In the following description, a “lower layer” means a layer that is formed in a process preceding a process in which a layer as a comparison target is formed, while an “upper layer” means a layer that is formed in a process following a process in which a layer as a comparison target is formed. In the following description, a description of “from A to B” for two numbers A and B means “equal to or greater than A and equal to or less than B”, unless otherwise specified.

Overall Configuration of Light-Emitting Element

A light-emitting element according to an embodiment of the disclosure includes a first electrode, a second electrode, a first nanoparticle layer disposed between the first electrode and the second electrode and including first nanoparticles, and a second nanoparticle layer disposed between the second electrode and the first nanoparticle layer, being in contact with the first nanoparticle layer, and including second nanoparticles. The light-emitting element according to an embodiment of the disclosure includes a ligand, including at least two coordinating functional groups, at an interface between the first nanoparticle layer and the second nanoparticle layer. The ligand includes a first coordinating functional group for coordinating to the first nanoparticles and a second coordinating functional group for coordinating to the second nanoparticles, and bonds the first nanoparticles and the second nanoparticles at the interface between the first nanoparticle layer and the second nanoparticle layer (in other words, an interface between the first nanoparticles and the second nanoparticles).

In the present embodiment, a case where the first nanoparticles are quantum dots and the second nanoparticles contain a carrier transport material will be described as an example.

Hereinafter, as an example of the light-emitting element according to the present embodiment, a case is described as an example where the first electrode (lower electrode) is an anode electrode, the second electrode (upper electrode) is a cathode electrode, the first nanoparticle layer on the first electrode side (lower layer side) is a light-emitting layer, and the second nanoparticle layer on the second electrode side (upper layer side) is an electron transport layer.

FIG. 1 is a cross-sectional view illustrating an example of an overall configuration of a light-emitting element 1 according to the present embodiment in which a main portion of the light-emitting element is enlarged and schematically illustrated.

The light-emitting element 1 according to the present embodiment is an electroluminescent element that emits light when a voltage is applied to a light-emitting layer (hereinafter, referred to as “EML”) 13. Note that the light-emitting element 1 may be used as, for example, a light source of a light-emitting device such as a display device or an illumination device.

The light-emitting element 1 illustrated in FIG. 1 includes an anode electrode 11, a positive hole transport layer (hereinafter referred to as “HTL”) 12, the EML 13, an electron transport layer (hereinafter referred to as “ETL”) 14, and a cathode electrode 15. The ETL 14 is layered on the EML 13 to be adjacent to the EML 13. The anode electrode 11 and the cathode electrode 15 are connected to a power supply (not illustrated) (for example, a DC power supply), and thus a voltage is applied therebetween.

In the example illustrated in FIG. 1, the anode electrode 11, the HTL 12, the EML 13, the ETL 14, and the cathode electrode 15 are layered on a substrate 10 in this order from the substrate 10 side so as to be adjacent to each other.

The following description is given with a direction from the anode electrode 11 to the cathode electrode 15 referred to as an upward direction, and with the direction opposite thereto referred to as a downward direction. In the example illustrated in FIG. 1, the anode electrode 11 is the lower electrode provided on the substrate 10, and the cathode electrode 15 is the upper electrode provided more on the upper side than the lower electrode.

However, the configuration of the light-emitting element 1 is not limited to the configuration described above. The light-emitting element 1 may have a configuration in which the cathode electrode 15 is the lower electrode, the anode electrode 11 is the upper electrode, and the cathode electrode 15, the ETL 14, the EML 13, the HTL 12, and the anode electrode 11 are layered in this order on the substrate 10.

The substrate 10 supports each layer from the anode electrode 11 to the cathode electrode 15, as described above.

In general, the lower electrode is formed on a substrate as a support body for forming the light-emitting element. Thus, the light-emitting element 1 may include the substrate 10 serving as the support body for forming each layer from the anode electrode 11 to the cathode electrode 15.

The substrate 10 may be, for example, a glass substrate, or may be a flexible substrate such as a plastic substrate or a plastic film. When the light-emitting element 1 is part of a light-emitting device including a plurality of the light-emitting elements 1, the substrate 10 may be an array substrate including a thin film transistor layer, as a drive circuit layer, provided with a plurality of thin film transistors (drive elements) for driving the light-emitting elements 1. In this case, the lower electrode (the anode electrode 11 in the example illustrated in FIG. 1) is electrically connected to a thin film transistor of the array substrate.

The substrate 10 may be constituted of a light-transmissive material or may be constituted of a light-reflective material. Still, in a case where the light-emitting element 1 has a bottom-emitting structure or a double-sided light-emitting structure, a transparent substrate made of a light-transmissive material is used for the substrate 10.

The anode electrode 11 is an electrode that supplies positive holes (holes) to the EML 13 when a voltage is applied. The cathode electrode 15 is an electrode that supplies electrons to the EML 13 when a voltage is applied.

At least one of the anode electrode 11 and the cathode electrode 15 is made of a light-transmissive material. Note that the anode electrode 11 or the cathode electrode 15 may be formed of a light-reflective material. The light-emitting element 1 can extract light from the side of the electrode made of a light-transmissive material.

The anode electrode 11 includes, for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 15 includes, for example, a material having a relatively small work function. Examples of the material include Al, silver (Ag), Ba, ytterbium (Yb), calcium (Ca), lithium (Li)-Al alloys, Mg—Al alloys, Mg—Ag alloys, Mg-indium (In) alloys, and Al-aluminum oxide (Al₂O₃) alloys.

The HTL 12 is a layer that transports positive holes supplied from the anode electrode 11 to the EML 13. The material of the HTL 12 is not particularly limited as long as it is a positive hole transport material, and a known positive hole transport material can be used.

An example of the positive hole transport material includes an electrically conductive polymer material with positive hole-transporting properties. Examples of such positive hole transport material include poly(3,4-ethylene dioxythiophene) (PEDOT), poly(3,4-ethylene dioxythiophene)-poly(styrenesulfonic acid) (PEDOT-PSS), poly(N-vinylcarbazole) (PVK), poly[(9,9-dyoctyl fluorenyl-2,7-diyl)-co-(4,4′-(N-(4-sec-butylphenyl))diphenylamine)] (TFB), 4,4′-bis(9-carbazolyl)-biphenyl (CBP), N,N′-di-[(1-naphthyl)-N, N′-diphenyl]-(1,1′-biphenyl)-4,4′-diamine (NPD), and derivatives of the above-described compounds. Note that the positive hole transport material may be an inorganic material having a positive hole-transporting properties or may contain an inorganic material having a positive hole-transporting properties. Only one type of these positive hole transport materials may be used, or two or more types thereof may be appropriately mixed and used.

The ETL 14 is a layer that transports electrons supplied from the cathode electrode 15 to the EML 13. In the present embodiment, the ETL 14 is the second nanoparticle layer, and the ETL 14 includes, for example, nanoparticles 141 made of an electron transport material (first carrier transport material) as the second nanoparticles. Thus, in the present embodiment, the second nanoparticles are, for example, an electron transport material.

The nanoparticles 141 include nano-sized fine particles (inorganic nanoparticles) made of an inorganic compound and having electron-transporting properties. The electron transport material used for the inorganic nanoparticles having electron-transporting properties includes an inorganic compound such as an n-type semiconductor. Examples of the n-type semiconductor include metal oxide, a group II-VI compound semiconductor, a group III-V compound semiconductor, a group IV-IV compound semiconductor, and an amorphous semiconductor. Examples of the metal oxide include zinc oxide (ZnO), titanium oxide (TiO₂), indium oxide (In₂O₃), tin oxide (SnO, SnO₂), and cerium oxide (CeO₂). Examples of the group II-VI compound semiconductor include zinc sulfide (ZnS) and zinc selenide (ZnSe). Examples of the group III-V compound semiconductor include aluminum arsenide (AlAs), gallium arsenide (GaAs), indium arsenide (InAs), aluminum nitride (AlN), gallium nitride (GaN), indium nitride (InN), and gallium phosphide (GaP). Examples of the group IV-IV compound semiconductor include silicon germanium (SiGe) and silicon carbide (SiC). Examples of the amorphous semiconductor include n-type hydrogenated amorphous silicon, and n-type hydrogenated amorphous silicon carbide. Only one type of these electron transport materials may be used, or two or more types thereof may be appropriately mixed and used.

These electron transport materials are excellent in durability and in reliability, and the film formation can be carried out by an application method and is easy to be carried out. Among them, the electron transport material is desirably metal oxide nanoparticles (in other words, fine particles of metal oxide or mixed crystal-based fine particles of the metal oxide), and is particularly desirably a semiconductor material containing zinc (Zn) atoms. The semiconductor material containing Zn atoms has high strength and can provide the light-emitting element 1 having particularly high mechanical strength.

The number mean particle size (diameters) of the nanoparticles 141 is, for example, in a range of from 1 to 15 nm, and the number of overlapping layers of the nanoparticles 141 in the ETL 14 is, for example, from 1 to 10 layers. The layer thickness of the HTL 12 and the layer thickness of the ETL 14 which may be known layer thicknesses, are for example, in a range of from 1 to 150 nm.

The EML 13 is a layer that includes a luminescent material and emits light by recombination of electrons transported from the cathode electrode 15 and positive holes transported from the anode electrode 11.

The light-emitting element 1 according to the present embodiment is a quantum-dot light emitting diode (QLED), and the EML 13 contains nano-sized quantum dots (hereinafter, referred to as “QDs”) 131 as a luminescent material.

With the light-emitting element 1 according to the present embodiment, positive holes and electrons recombine inside the EML 13 in response to a drive current between the anode electrode 11 and the cathode electrode 15, and light (fluorescence or phosphorescence for example) is emitted when the excitons generated as a result transition from a conduction band level to a valence band level of the QDs 131.

The QDs 131 are a luminescent material that has a valence band level and a conduction band level and emits light through recombination of a positive hole at the valence band level with an electron at the conduction band level.

QDs are also referred to as semiconductor nanoparticles. In the example illustrated in FIG. 1, the EML 13 is the first nanoparticle layer, and the first nanoparticles are the QDs 131 (first quantum dots).

The QDs 131 are not particularly limited, and various known QDs may be employed. Examples of the QDs 131 include a QD phosphor.

The QDs 131 may include, for example, a semiconductor material formed of an element of at least one type selected from the group consisting of cadmium (Cd), sulfur (S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg). Note that general QDs contain Zn. Thus, the QDs 131 may be, for example, a semiconductor material including Zn atoms.

Further, the QDs 131 may be a two-component core type, a three-component core type, a four-component core type, a core-shell type, or a core multi-shell type. Further, the QDs 131 may include doped nanoparticles, or may include a compositionally graded structure in which a composition gradually changes. In the present embodiment, as an example, for example, a core-shell type QD having a core-shell structure including a core and a shell is used for the QDs 131. For example, a nano-sized crystal of the semiconductor material can be used for the core. The shell is provided outside the core so as to cover the core.

As an example, the particle size of the core is, for example, from about 1 to 10 nm, and the outermost particle size of the QDs 131 even when including the shell is, for example, from about 1 to 15 nm, and is preferably about from 3 to 15 nm. The number of overlapping layers of the QDs 131 in the EML 13 is, for example, from 1 to 10 layers. The layer thickness of the EML 13 may be a known layer thickness, and is, for example, in a range of from about 1 to 150 nm, and preferably in a range of from 3 to 150 nm. In the present embodiment, the “particle size” refers to a “number mean particle size” unless otherwise specified.

When the core-shell type QD is used for the QDs 131, the wavelength of light emitted by the QDs 131 is proportional to the particle size of the core and does not depend on the outermost particle size of the QDs 131 including the shell.

As illustrated in FIG. 1, the light-emitting element 1 according to the present embodiment has a ligand 21 including at least two coordinating functional groups (adsorption groups) at the interface between the EML 13 and the ETL 14.

The ligand 21 includes a coordinating functional group for coordinating (adsorbing) to the first nanoparticles as the first coordinating functional group, and includes a coordinating functional group for coordinating (adsorbing) to the second nanoparticles as the second coordinating functional group. The first coordinating functional group and the second coordinating functional group may be the same type of coordinating functional group or may be different types of coordinating functional groups. Thus, the ligand 21 may include at least two coordinating functional groups of at least one type.

Therefore, the ligand 21 according to the present embodiment includes a coordinating functional group for coordinating (adsorbing) to the QDs 131 as the first coordinating functional group, and includes a coordinating functional group for coordinating (adsorbing) to the nanoparticles 141 as the second coordinating functional group. The ligand 21 according to the present embodiment coordinates to the surfaces of the QDs 131 and the nanoparticles 141, with the QDs 131 and the nanoparticles 141 being receptors, and thus serves as a surface-modifying agent to modify the surfaces of the QDs 131 and the nanoparticles 141.

The first coordinating functional group is not particularly limited as long as it is a functional group that can coordinate to the QDs 131. Examples of the first coordinating functional group include at least one functional group selected from the group consisting of a thiol (—SH) group, an amino (—NR₂) group, a carboxyl (—C(═O)OH) group, a phosphonic (—P(═O)(OR)₂) group, a phosphine (—PR₂) group, and a phosphine oxide (—P(═O)R₂) group. The R groups each independently represent a hydrogen atom or any organic group such as an alkyl group or an aryl group. The amino group may be any of primary, secondary, and tertiary amino groups, but among them, a primary amino (—NH₂) group is particularly preferable. The phosphonic group, the phosphine group, and the phosphine oxide group may also be any of primary, secondary, and tertiary groups, but the phosphonic group, the phosphine group, and the phosphine oxide group are particularly preferably a tertiary phosphonic (—P(═O)(OR)₂) group, a tertiary phosphine (—PR₂) group, and a tertiary phosphine oxide (—P(═O)R₂) group, respectively, with the R group being an alkyl group. Examples of the alkyl group in the tertiary phosphonic group, the tertiary phosphine group, and the tertiary phosphine oxide group include an alkyl group having from 1 to 20 carbon atoms.

The second coordinating functional group is not particularly limited as long as it is a functional group that can coordinate to the nanoparticles 141. Examples of the second coordinating functional group include at least one functional group selected from the group consisting of the coordinating functional groups exemplified as the first coordinating functional group. As in the case of the first coordinating functional group, when the second coordinating functional group is, for example, an amino group, the amino group may be any of primary, secondary, and tertiary amino groups, but among them, a primary amino group is particularly preferable. When the second coordinating functional group is, for example, any of a phosphonic group, a phosphine group, and a phosphine oxide group, the phosphonic group, the phosphine group, and the phosphine oxide group may be any of primary, secondary, and tertiary, but the phosphonic group, the phosphine group, and the phosphine oxide group are particularly preferably a tertiary phosphonic group, a tertiary phosphine group, and a tertiary phosphine oxide group, respectively, with the R group being an alkyl group, as in the case of the first coordinating functional group. Also in this case, examples of the alkyl group in the tertiary phosphonic group, the tertiary phosphine group, and the tertiary phosphine oxide group include an alkyl group having from 1 to 20 carbon atoms.

As described above, typical QDs contain Zn. For example, as illustrated in a specific example described below, Zn is contained in the shell (outermost surface). As described above, the electron transport material is preferably metal oxide nanoparticles, and is particularly preferably a semiconductor material containing Zn atoms. The thiol group has higher coordination properties with respect to nanoparticles containing Zn than an amino group, a carboxyl group, a phosphonic group, a phosphine group, and a phosphine oxide group. Therefore, more preferably, the QDs 131 and the nanoparticles 141 each contain a semiconductor material containing Zn, and the first coordinating functional group and the second coordinating functional group are each a thiol group.

In the present embodiment, a monomer that is a compound having a molecular weight of 1000 or less is used as the ligand 21. That is, in the present embodiment, a monomer having at least two coordinating functional groups including the first coordinating functional group and the second coordinating functional group is used as the ligand 21. By performing mass spectrometry using time-of-flight secondary ion mass spectrometry (TOF-SIMS) or the like, for example, the molecular structure of the ligand (specifically, the molecular structure of the ligand 21) included in the interface between the EML 13 and the ETL 14 can be determined with high accuracy.

The ligand 21 is desirably, for example, a monomer including at least two coordinating functional groups including the first coordinating functional group and the second coordinating functional group, and a substituted or unsubstituted alkylene group or a substituted or unsubstituted unsaturated hydrocarbon group as a spacer (spacer group) bonded to the coordinating functional groups and positioned between the coordinating functional groups. Here, the substituted or unsubstituted alkylene group refers to an alkylene group that may be unsubstituted or may have a substituent. Similarly, the substituted or unsubstituted unsaturated hydrocarbon group refers to an unsaturated hydrocarbon group that may be unsubstituted or may have a substituent. Here, “may have a substituent” includes both a case in which a hydrogen atom (—H) is substituted by a monovalent group and a case in which a methylene group (—CH₂—) is substituted by a divalent group.

The alkylene group may be chain-like or cyclic. The unsaturated hydrocarbon group may be an aliphatic hydrocarbon group or an aromatic hydrocarbon group.

Examples of the substituent include an aliphatic hydrocarbon group, an aromatic hydrocarbon group, an aromatic heterocyclic group, and a hydroxyl group. The hydrogen atom may be substituted by the coordinating functional group.

The ligand 21 may have at least two coordinating functional groups of at least one type including the first coordinating functional group and the second coordinating functional group, and at least one polar bonding group of at least one type at a site other than the site coordinating to the QDs 131 and the site coordinating to the nanoparticles 141 (in other words, a site other than the coordinating functional groups).

The polar bonding group is not particularly limited as long as it is a bonding group that imparts polarity to the ligand 21 (that is, a bonding group that imparts a charge distribution bias in bonding to the ligand 21), and examples thereof include at least one bonding group selected from the group consisting of an ether bonding (—O—) group, a sulfide bonding (—S—) group, an imine bonding (—NH—) group, an ester bonding (—C(═O)O—) group, an amide bonding (—C(═O)NR′—) group, and a carbonyl (—C(═O)—) group. The R′ group represents a hydrogen atom or any organic group such as an alkyl group or an aryl group.

When the ligand 21 has a polar bonding group as described above, the ligand 21 preferably has an alkylene group having from 1 to 4 carbon atoms directly bonded to the polar bonding group.

When at least one of the nanoparticles bonded via the ligand 21 is a QD as described above, too short distance between the nanoparticles bonded via the ligand 21 (in the present embodiment, the distance between the QDs 131 and the nanoparticles 141) may cause deactivation of the QD. When the ligand 21 has a polar bonding group as described above, the ligand 21 preferably has an alkylene group having from 1 to 4 carbon atoms directly bonded to the polar bonding group, whereby a decrease in the light-emission characteristics due to deactivation of the QDs 131 can be suppressed.

Examples of the ligand 21 include a monomer having the first coordinating functional group and the second coordinating functional group at both respective ends of the main chain. Examples of the ligand 21 include at least one type of ligand selected from the group consisting of ligands represented by the following general formula (1) and the following general formula (2).

R¹—A¹—A²—(CH₂)ₙ—R² (1)

R³—Z—R⁴ (2)

In the general formula (1) above, R¹ represents one of the first coordinating functional group and the second coordinating functional group, and R² represents the other of the first coordinating functional group and the second coordinating functional group. The first coordinating functional group and the second coordinating functional group may be the same coordinating functional group or may be different coordinating functional groups. Therefore, R¹ and R² may be the same coordinating functional group or may be different coordinating functional groups.

A¹ represents a substituted or unsubstituted —((CH₂)ₘ₁—X¹)ₘ₂— group. A² represents direct bonding, an X² group, or a substituted or unsubstituted —((CH₂)ₘ₃—X²)ₘ₄— group. X¹ and X² represent polar bonding groups different from each other. n and m1 to m4 each independently represent an integer of 1 or more. Desirably, n, m1, and m3 are each independently an integer of from 1 to 4, and m2 and m4 are each independently an integer of from 1 to 10.

The substituted or unsubstituted —((CH₂)ₘ₁—X¹)ₘ₂— group indicates that the —((CH₂)ₘ₁—X¹)ₘ₂— group may be unsubstituted or may have a substituent. Similarly, the substituted or unsubstituted —((CH₂)ₘ₃—X²)ₘ₄— group indicates that the —((CH₂)ₘ₃—X²)ₘ₄— group may be unsubstituted or may have a substituent.

As described above, “may have a substituent” includes both a case in which a hydrogen atom (—H) is substituted by a monovalent group and a case in which a methylene group (—CH₂—) is substituted by a divalent group.

Even in the case where the alkylene group is bonded to the polar bonding group as described above, the alkylene group may be chain-like or cyclic. Thus, the —((CH₂)ₘ₁—X¹)ₘ₂— group and the —((CH₂)ₘ₃—X²)ₘ₄— group may be chain-like or cyclic.

As described above, examples of the substituent include an aliphatic hydrocarbon group, an aromatic hydrocarbon group, an aromatic heterocyclic group, and a hydroxyl group. The hydrogen atom may be substituted by the coordinating functional group. Therefore, the ligand represented by the general formula (1) above may be a bifunctional molecule having the coordinating functional groups that may be the same or different at both ends of the main chain, or may be a polyfunctional molecule having the coordinating functional groups at both ends of the main chain and at the side chain.

In the general formula (2) above, R³ represents one of the first coordinating functional group and the second coordinating functional group, and R⁴ represents the other of the first coordinating functional group and the second coordinating functional group. As described above, the first coordinating functional group and the second coordinating functional group may be the same coordinating functional group or may be different coordinating functional groups. Therefore, R³ and R⁴ may be the same coordinating functional group or may be different coordinating functional groups.

Z represents a substituted or unsubstituted alkylene group having from 1 to 10 carbon atoms, or a substituted or unsubstituted unsaturated hydrocarbon group having from 2 to 10 carbon atoms.

By using as the ligand 21 at least one ligand selected from the group consisting of ligands represented by the general formula (1) above and the general formula (2) above, the ligand 21 coordinates to each of the QDs 131 and the nanoparticles 141, and the EML 13 and the ETL 14 having high liquid resistance to polar solvents and non-polar solvents (apolar solvents) can be formed.

This effect is unique to the case where the ligand 21 is a monomer. A polymer has many repeats of a unit structure (monomer) and generally has about 1,000 or more atoms or is polymerized to have a molecular weight of 10,000 or more. An oligomer has fewer repeats of a unit structure (monomer) and generally has a molecular weight of from 1,000 to 10,000. A polymerized or oligomerized ligand consumes coordinating functional groups such as thiol that can coordinate to nanoparticles (the QDs 131 and the nanoparticles 141 in the present embodiment) and chemically reacts to extend a chain. Therefore, as the molecules become larger, the amount or density of the coordinating functional groups that can coordinate to the nanoparticles decreases. For this reason, the polymerized or oligomerized ligand is a factor that greatly decreases the room for or probability of coordinating to the nanoparticles and the probability of exhibiting the effect of insolubilization to connect the nanoparticles to each other.

According to the present embodiment, as illustrated in FIG. 1, since the light-emitting element 1 has the ligand 21 at the interface between the EML 13 and the ETL 14, the QDs 131 and the nanoparticles 141 can be immobilized (bonded) via the ligand 21 at the interface between the EML 13 and the ETL 14. Therefore, according to the present embodiment, it is possible to prevent or suppress at the interface between the EML 13 and the ETL 14, mixing of the QDs 131 and the nanoparticles 141 and formation of a mixed layer of the QDs 131 and the nanoparticles 141 when a voltage for driving the light-emitting element 1 is applied to the light-emitting element 1. Therefore, according to the present embodiment, electromigration at the interface between the EML 13 and the ETL 14 can be suppressed or prevented, and the influence of electromigration at the interface between the EML 13 and the ETL 14 can be suppressed or eliminated. Further, according to the present embodiment, since the QDs 131 and the nanoparticles 141 can be immobilized via the ligand 21 at the interface between the EML 13 and the ETL 14, layer peeling between the EML 13 and the ETL 14 at the interface between the EML 13 and the ETL 14 can be suppressed.

According to the present embodiment, since the QDs 131 and the nanoparticles 141 are bonded to each other by the ligand 21 at the interface between the EML 13 and the ETL 14, electrons are injected from the nanoparticles 141 to the QDs 131 via the ligand 21 common to the QDs 131 and the nanoparticles 141. Therefore, the loss of electrons at the time of electron injection in the light-emitting element 1 can be reduced.

The number of atoms constituting the straight chain of the ligand 21 is preferably about the same as the number of atoms constituting the straight chain of a ligand used in the related art even when the ligand 21 includes the polar bonding groups as described above. In addition, the number of molecules of the ligand 21 is preferably not so large that it can be easily dissolved (dispersed) in a non-polar solvent.

Thus, in the case where A² is direct bonding, the ligand represented by the general formula (1) preferably satisfies 2≤m1×m2+n≤20, and more preferably satisfies 3≤m1×m2+n≤10.

As described above, when at least one of the nanoparticles bonded via the ligand 21 is a QD, too short distance between the nanoparticles bonded via the ligand 21 (in the present embodiment, the distance between the QDs 131 and the nanoparticles 141) may cause deactivation of the QD.

Further, as described above, the first coordinating functional group and the second coordinating functional group may be the same coordinating functional group. All of the above-described coordinating functional groups can each coordinate to the QDs 131 and to the nanoparticles 141. For this reason, the ligand 21 immobilizes the QDs 131 and the nanoparticles 141 at the interface between the EML 13 and the ETL 14 as described above, and bonds the QDs 131 to each other and bonds the nanoparticles 141 to each other in the vicinity of the interface.

If the distance between the QDs 131 bonded via the ligand 21 is too short, the QDs 131 interact with each other. As a result, electrons migrate between the QDs 131, and the QDs 131 may be deactivated. When the QDs 131 are deactivated, the luminous efficiency and the light-emission intensity of the light-emitting element 1 may be compromised.

According to NPL 1, when the distance between the cores of QDs is about 9 nm, the Förster resonance energy transfer (FRET) efficiency are about 6% or less. This indicates that FRET is suppressed when the distance between the cores of the QDs is about 9 nm. In addition, the shell thickness of general commercial QD is about from 1 to 2 nm. Therefore, when the distance between adjacent QDs including the shells (in other words, the distance between the outer surfaces of the shells of adjacent QDs) is set to be greater than or equal to 5 nm, the FRET efficiency can be reduced.

Therefore, in order to prevent the deactivation of the QDs 131, it is preferable that the shortest distance between the adjacent nanoparticles bonded via the ligand 21, in particular, the shortest distance between the adjacent QDs 131 be equal to or larger than the 5 nm.

On the other hand, if the shortest distance between the adjacent nanoparticles bonded via the ligand 21 is too long, the proportion of the nanoparticles in the region where the nanoparticles are bonded via the ligands 21 is small, and the luminous efficiency may be compromised. As a result, the light-emission intensity may be compromised. On the other hand, if the length of the ligand 21 is too long, light-emission unevenness may occur. In addition, a longer length of the ligand 21 leads to a larger the movable range of each of the nanoparticles immobilized by the ligand 21 at the interface between the first nanoparticle layer and the second nanoparticle layer (in the present embodiment, the interface between the EML 13 and the ETL 14). Therefore, the distance between the adjacent nanoparticles bonded by the ligand 21 (in the present embodiment, the distance between the adjacent QDs 131 and the nanoparticles 141, the distance between the adjacent QDs 131, and the distance between the adjacent nanoparticles 141) is preferably equal to or less than the 50 nm.

The distance between nanoparticles indicates a value obtained by subtracting the number mean particle size of the semiconductor nanoparticles from the average value of a center-to-center distance between the adjacent nanoparticles (average nanoparticle center-to-center distance). The average nanoparticle center-to-center distance can be measured using small angle X-ray scattering pattern or a cross-sectional transmission electron microscope (TEM) image of a film containing the nanoparticles for example. Similarly, the number mean particle size of the nanoparticles (such as, for example, the QDs 131 and the nanoparticles 141) can be measured using, for example, the cross-sectional TEM image. The number mean particle size of the nanoparticles indicates the diameter of the nanoparticle at 50% of the integrated value in the particle size distribution. The number mean particle size of the nanoparticles when obtained from the cross-sectional TEM image can be obtained, for example, as follows. First, from the outer shape of each cross section of a predetermined number (30 for example) of cross-sections of nanoparticles close to each other, the area of the cross section of each nanoparticle is obtained by, for example, TEM. Next, all of these nanoparticles are assumed to be circular, and the diameter corresponding to the area of the circle that is the area of each cross section is calculated. Then, a mean value thereof is calculated.

When m1×m2+n is set to be 2 or more, the ligand represented by the general formula (1) described above has the first coordinating functional group and the second coordinating functional group at both ends of the ligand and has, between the groups, an alkylene group directly bonded to the polar bonding group. With this configuration, deterioration of the light-emission characteristics due to deactivation of the QDs 131 can be suppressed. In addition, when m1×m2+n is set to be 20 or less, it is possible to form the light-emitting element 1 featuring high luminous efficiency, with the proportion of the nanoparticles in the region where the nanoparticles are bonded to each other via the ligand 21 being high. In addition, when m1×m2+n is set to be 20 or less, it is possible to suppress light-emission unevenness as a result of the ligand 21 represented by the general formula (1) being too long. In addition, when m1×m2+n is set to be 20 or less, the bonding strength between the nanoparticles via the ligand 21 represented by the general formula (1) can be further increased. Therefore, it is possible to obtain a layered body in which layer peeling between adjacent nanoparticle layer patterns (the interface between the EML 13 and the ETL 14 in the present embodiment) can be more reliably suppressed. When m1×m2+n is set to be 20 or less, the movable range of the nanoparticles immobilized by the ligand 21 at the interface between the first nanoparticle layer and the second nanoparticle layer (in the present embodiment, the interface between the EML 13 and the ETL 14) can be more effectively limited. Therefore, electromigration at the interface can be more effectively suppressed or prevented, and the influence of electromigration at the interface can be further suppressed or eliminated.

In addition, when m1×m2+n is set to be 10 or less, it is possible to form the light-emitting element 1 featuring higher luminous efficiency, with the proportion of the nanoparticles in the region where the nanoparticles are bonded to each other via the ligand 21 being higher. In addition, when m1×m2+n is set to be 10 or less, the bonding strength between the nanoparticles via the ligand 21 represented by the general formula (1) can be even further increased. Therefore, it is possible to obtain a layered body in which layer peeling between adjacent nanoparticle layer patterns can be sufficiently suppressed. When m1×m2+n is set to be 10 or less, the movable range of the nanoparticles immobilized by the ligand 21 at the interface between the first nanoparticle layer and the second nanoparticle layer can be even more effectively limited. Therefore, electromigration at the interface can be even more effectively suppressed or prevented, and the influence of electromigration at the interface can be even further suppressed or eliminated. When m1×m2+n is set to be 3 or more, deactivation of the QDs 131 can be more reliably suppressed, whereby deterioration of the light-emission characteristics due to the deactivation of the QDs 131 can be more reliably suppressed. Thus, when m1×m2+n is set to be 3 or more, deactivation of the QDs 131 can be more reliably suppressed, whereby deterioration of the light-emission characteristics due to the deactivation of the QDs 131 can be more reliably suppressed.

In addition, in the ligand represented by the general formula (1) above, when A² is the —((CH₂)ₘ₃—X²)ₘ₄— group, it is desirable that 2≤m1×m2+m3×m4+n≤20, and more desirable that 3≤m1×m2+m3×m4+n≤10.

As described above, if the distance between the nanoparticles via the ligand 21 is too short, the QDs 131 may be deactivated, resulting in compromised luminous efficiency. When m1×m2+m3×m4+n is set to be 2 or more, the ligand 21 represented by the general formula (1) described above has the coordinating functional groups at both ends and has, between the groups, an alkylene group directly bonded to the polar bonding group. With this configuration, deterioration of the light-emission characteristics due to deactivation of the QDs 131 can be suppressed. In addition, when m1×m2+m3×m4+n is set to be 20 or less, it is possible to form the light-emitting element 1 featuring high luminous efficiency, with the proportion of the nanoparticles in the region where the nanoparticles are bonded to each other via the ligand 21 being high. In addition, when m1×m2+m3×m4+n is set to be 20 or less, it is possible to suppress light-emission unevenness as a result of the ligand 21 represented by the general formula (1) being too long. In addition, when m1×m2+m3×m4+n is set to be 20 or less, the bonding strength between the nanoparticles via the ligand 21 represented by the general formula (1) can be further increased. Therefore, it is possible to obtain a layered body in which layer peeling between adjacent nanoparticle layer patterns can be more reliably suppressed. When m1×m2+m3×m4+n is set to be 20 or less, the movable range of the nanoparticles immobilized by the ligand 21 at the interface between the first nanoparticle layer and the second nanoparticle layer can be more effectively limited. Therefore, electromigration at the interface can be more effectively suppressed or prevented, and the influence of electromigration at the interface can be further suppressed or eliminated.

In addition, when m1×m2+m3×m4+n is set to be 10 or less, it is possible to form the light-emitting element 1 featuring higher luminous efficiency, with the proportion of the nanoparticles in the region where the nanoparticles are bonded to each other via the ligand 21 being higher. In addition, when m1×m2+m3×m4+n is set to be 10 or less, the bonding strength between the nanoparticles via the ligand 21 represented by the general formula (1) can be even further increased. Therefore, it is possible to obtain a layered body in which layer peeling between adjacent nanoparticle layer patterns can be sufficiently suppressed. When m1×m2+m3×m4+n is set to be 10 or less, the movable range of the nanoparticles immobilized by the ligand 21 at the interface between the first nanoparticle layer and the second nanoparticle layer can be even more effectively limited. Therefore, electromigration at the interface can be even more effectively suppressed or prevented, and the influence of electromigration at the interface can be even further suppressed or eliminated. When m1×m2+m3×m4+n is set to be 3 or more, deactivation of the QDs 131 can be more reliably suppressed, whereby deterioration of the light-emission characteristics due to the deactivation of the QDs 131 can be more reliably suppressed.

In the ligand represented by the general formula (2) above, as described above, Z represents a substituted or unsubstituted alkylene group having from 1 to 10 carbon atoms, or a substituted or unsubstituted unsaturated hydrocarbon group having from 2 to 10 carbon atoms. Note that the substituted or unsubstituted alkylene group and the substituted or unsubstituted unsaturated hydrocarbon group are as described above. The substituent is also as described above. Therefore, the ligand represented by the general formula (2) above may be a bifunctional molecule having the coordinating functional groups that may be the same or different at both ends of the main chain, or may be a polyfunctional molecule having the coordinating functional groups at both ends of the main chain and at the side chain.

The ligand represented by the general formula (2) above is more preferably a ligand in which Z above is a substituted or unsubstituted alkylene group having from 4 to 10 carbon atoms, or a substituted or unsubstituted unsaturated hydrocarbon group having from 4 to 10 carbon atoms.

When the number of carbon atoms in Z exceeds 10, it becomes difficult to dissolve the ligand represented by the general formula (2) above in a polar solvent, for example. When the number of carbon atoms in Z is 4 or more, the distance between the nanoparticles to which the ligand represented by the general formula (2) above coordinates increases, and thus deactivation of the QDs 131 can be prevented and the luminous efficiency can be improved.

As described above, it suffices if the ligand 21 is a ligand that has at least two coordinating functional groups of at least one type and that can coordinate to the QDs 131 and the nanoparticles 141 (in other words, a ligand including the first coordinating functional group and the second coordinating functional group). Therefore, the ligand 21 is not particularly limited as long as it satisfies the conditions described above, and as an example, specific examples thereof include 1,2-ethanedithiol, 1,2-propanedithiol, 1,3-propanedithiol, 1,2-butanedithiol, 1,3-butanedithiol, 1,4-butanedithiol, 2,3-butanedithiol, 1,6-hexanedithiol, 1,8-octanedithiol, 1,2-propanediamine, 1,3-propanediamine, 1,4-butanediamine, 3-amino-5-mercapto-1,2,4-triazole, 2-aminobenzenethiol, toluene-3,4-dithiol, dithioerythritol, dihydrolipoic acid, thiolactic acid, 3-mercaptopropionic acid, 1-amino-3,6,9,12,15,18-hexaoxahenicosan-21-oic acid, 2-[2-(2-aminoethoxy)ethoxy]acetic acid, 2,2′-(ethylenedioxy)diethanethiol, 2,2′-oxydiethanethiol, (12-phosphonododecyl)phosphonic acid, 11-mercaptoundecylphosphonic acid, 11-phosphonoundecanoic acid, and ethylene glycol bis(3-mercaptopropionate). A single type of these ligands may be used alone, or two or more types may be mixed and used, as appropriate.

Among these exemplified ligands, 2,2′-(ethylenedioxy)diethanethiol is particularly preferable as the ligand 21.

By using 2,2′-(ethylenedioxy)diethanethiol as the ligand 21, it is possible to form the light-emitting element 1 featuring higher luminous efficiency, with the proportion of the nanoparticles in the region where the nanoparticles are bonded to each other via the ligand 21 being higher. In addition, by using 2,2′-(ethylenedioxy)diethanethiol as the ligand 21, a decrease in the light-emission characteristics due to deactivation of the QDs 131 can be suppressed, and light-emission unevenness due to the ligand 21 becoming too long can also be suppressed. In addition, the bonding strength between the nanoparticles via the ligand 21 can be increased, and layer peeling between the adjacent nanoparticle layer patterns can be sufficiently suppressed. Moreover, electromigration at the interface between the first nanoparticle layer and the second nanoparticle layer can be suppressed or prevented, and the influence of electromigration at the interface can be suppressed or eliminated.

Of the EML 13 and the ETL 14, at least the EML 13 may further contain a monofunctional ligand 25 having one coordinating functional group (adsorption group) described above in addition to the ligand 21.

The ligand 25 coordinates to the surfaces of the QDs 131 with the QDs 131 being the receptor, and serves as the surface-modifying agent to modify the surfaces of the QDs 131. The ligand 25 is not particularly limited as long as it is a monofunctional ligand, and may be, for example, a monomer or an oligomer.

Examples of the ligand 25 having one thiol group as the coordinating functional group include thiol-based ligands such as octadecanethiol, hexanedecanethiol, tetradecanethiol, dodecanethiol, decanethiol, and octanethiol.

Examples of the ligand 25 having one amino group as the coordinating functional group include primary amine-based ligands such as oleylamine, stearyl (octadecyl) amine, dodecyl (lauryl) amine, decylamine, and octylamine.

Examples of the ligand 25 having one carboxyl group as the coordinating functional group include fatty acid-based ligands such as oleic acid, stearic acid, palmitic acid, myristic acid, lauryl (dodecanoic) acid, decanoic acid, and octanoic acid.

Examples of the ligand 25 having one phosphonic group as the coordinating functional group include phosphonic acid-based ligands such as hexadecylphosphonic acid and hexylphosphonic acid.

Examples of the ligand 25 having one phosphine group as the coordinating functional group include phosphine-based ligands such as trioctylphosphine, triphenylphosphine, and tributylphosphine.

Examples of the ligand 25 having one phosphine oxide group as the coordinating functional group include phosphine oxide-based ligands such as trioctylphosphine oxide, triphenylphosphine oxide, and tributylphosphine oxide.

As will be described below in detail, in the present embodiment, a layer containing the nanoparticles 141 (second nanoparticle containing layer) to be the ETL 14 is formed on a layer containing the QDs 131 (first nanoparticle containing layer) to be the EML 13, and a ligand solution containing the ligand 21 is supplied from above the layer. Then, the ligand solution containing the ligand 21 is permeated from the layer containing the nanoparticles 141 on the upper layer side toward the layer containing the QDs 131 on the lower layer side. Thus, in the present embodiment, the ligand 21 is coordinated to each of the QDs 131 and the nanoparticles 141 at the interface between the layer containing the nanoparticles 141 and the layer containing the QDs 131. At this time, the ligand 25 coordinating to the QDs 131 located at the interface before the supply of the ligand solution is exchanged with the ligand 21 as a result of supplying the ligand solution. Thus, in the present embodiment, the ligand 21 is coordinated to each of the QDs 131 and the nanoparticles 141 at the interface between ETL 14 formed by the layer containing the nanoparticles 141 and the EML 13 formed by the layer containing the QDs 131. The EML 13 may have the ligand 21 at least at the interface between the EML 13 and the ETL 14.

Therefore, as an example, the light-emitting element 1 may have a configuration in which the content of the ligand 21 in the EML 13 is larger in part of the EML 13 closer to the interface with the ETL 14 and is smaller in part farther from the interface with the ETL 14. In addition, as an example, the light-emitting element 1 may have a configuration in which the content of the ligand 25 in the EML 13 is smaller in part of the EML 13 closer to the interface with the ETL 14 and is larger in part farther from the interface with the ETL 14. For example, the amount of ligand 21 at the interface between the EML 13 and the ETL 14 is preferably larger than that of ligand 25, and the ligand 21 is preferably used over the entirety. All the ligand in the EML 13 may be the ligand 21.

In recent years, the particle size of nanoparticles upon being used as the carrier transport material as described above has been gradually decreasing in order to improve the carrier transport efficiency.

Therefore, also in the present embodiment, in order to improve the dispersibility, the ETL material colloidal solution (ETL material dispersion liquid) containing the nanoparticles 141, which is used for forming the ETL 14, may further contain a ligand having a coordinating functional group (adsorption group) to coordinate (adsorb) to the nanoparticles 141. Examples of the ligand include a ligand having one coordinating functional group to coordinate to the nanoparticles 141.

As described above, examples of the coordinating functional group include at least one functional group selected from the group consisting of a thiol group, an amino group, a carboxyl group, a phosphonic group, a phosphine group, and a phosphine oxide group.

Therefore, examples of the ligand include the ligand described as an example of the ligand 25. For example, with the ligand 25 coordinated to the surface of the nanoparticles 141 in this manner, the aggregation of the nanoparticles 141 can be suppressed.

For example, when the ligand 25 coordinates to the surface of the nanoparticles 141, the ligand 25 on the surface of the nanoparticles 141 is also exchanged with the ligand 21 as a result of supplying the ligand solution containing the ligand 21.

Even if the ETL 14 contains the ligand 25, the effect of suppressing electromigration cannot be obtained. In addition, the loss of electrons at the time of electron injection cannot be reduced.

In the present embodiment, as described above, since the nanoparticles of each nanoparticle layer are bonded to each other by the ligand 21 at the interface between the nanoparticle layers layered adjacent to each other, effects such as suppression of electromigration and reduction of carrier loss at the time of carrier injection can be obtained.

In the present embodiment, as described above, the ligand solution is supplied onto the layer containing the nanoparticles 141, which is to be the ETL 14, and the ligand solution is permeated toward the layer containing the QDs 131, which is to be the EML 13 on the lower layer side. Thus, the ETL 14 may have a configuration in which the content of the ligand 21 in the ETL 14 is larger at a portion closer to the upper surface of the ETL 14 and is smaller at a portion farther from the upper surface of the ETL 14. In addition, the light-emitting element 1 may have a configuration in which the content of the ligand 25 in the ETL 14 is smaller at a portion closer to the upper surface of the ETL 14 and is larger at a portion farther from the upper surface of the ETL 14. Still as described above, the amount of ligand 21 at the interface between the EML 13 and the ETL 14 is preferably larger than that of ligand 25, and the ligand 21 is preferably used over the entirety. All the ligand in the ETL 14 may be the ligand 21.

In the present embodiment, as described above, the ligand solution is supplied onto the layer containing the nanoparticles 141, which is to be the ETL 14, and the ligand solution is permeated toward the layer containing the QDs 131, which is to be the EML 13. Therefore, the density of the nanoparticles 141 in the layer containing the nanoparticles 141 is desirably lower than the density of the QDs 131 in the layer containing the QDs 131. Thus, the gap between the nanoparticles 141 in the layer containing the nanoparticles 141 can be made larger than the gap between the QDs 131 in the layer containing the QDs 131. As a result, the ligand solution can be made easy to permeate to the interface between the layer containing the nanoparticles 141 and the layer containing the QDs 131. Therefore, as illustrated in FIG. 1, in the light-emitting element 1, the density of the nanoparticles 141 in the ETL 14 is desirably lower than the density of the QDs 131 in the EML 13.

In order to facilitate the permeation of the ligand solution to the interface between the layer containing the nanoparticles 141 and the layer containing the QDs 131 in this manner, the layer containing the nanoparticles 141 is preferably thinner than the layer containing the QDs 131. Therefore, as illustrated in FIG. 1, the ETL 14 is preferably thinner than the EML 13.

The light-emitting element 1 may include a functional layer other than the HTL 12, the EML 13, and the ETL 14 between the anode electrode 11 and the cathode electrode 15. As an example, for example, when the light-emitting element 1 includes the HTL 12 as illustrated in FIG. 1, the light-emitting element 1 may include a positive hole injection layer (HIL) between the anode electrode 11 and the HTL 12. When the light-emitting element 1 includes the ETL 14 as illustrated in FIG. 1, the light-emitting element 1 may include an electron injection layer (EIL) between the ETL 14 and the cathode electrode 15 for example.

The HIL has positive hole-transporting properties and has a function of enhancing positive hole injection efficiency into the EML 13. The HIL injects positive holes from the anode electrode 11 into the HTL 12. The positive hole transport material described above can be used for the HIL for example.

The EIL has electron-transporting properties and has a function of enhancing electron injection efficiency into the EML 13. The EIL injects electrons from the cathode electrode 15 into the ETL 14. An electron transport material is used for the EIL. The electron transport material may be formed by an inorganic material or may include an inorganic material. The electron transport material may be formed by an organic material or may include an organic material.

When the electron transport material is an inorganic material, the inorganic material includes an inorganic compound such as an n-type semiconductor as described above. Examples of the n-type semiconductor include metal oxide, a group II-VI compound semiconductor, a group III-V compound semiconductor, a group IV-IV compound semiconductor, and an amorphous semiconductor.

When the electron transport material is the organic material, examples of the organic material include 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), and tris(2,4,6-trimethyl-3-(pyridin-3-yl)phenyl)borane (3TPYMB).

Accordingly, the light-emitting element 1 may include a sealing member not illustrated.

### Manufacturing Method for Light-Emitting Element 1

Next, an example of a manufacturing method for the light-emitting element 1 according to the present embodiment will be described.

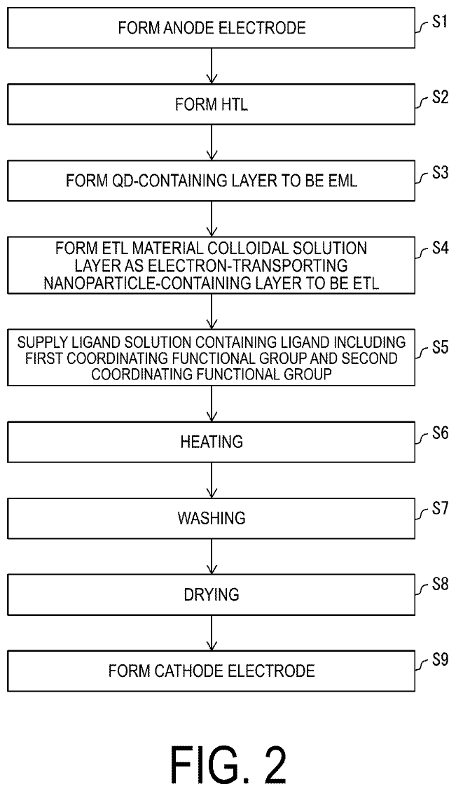

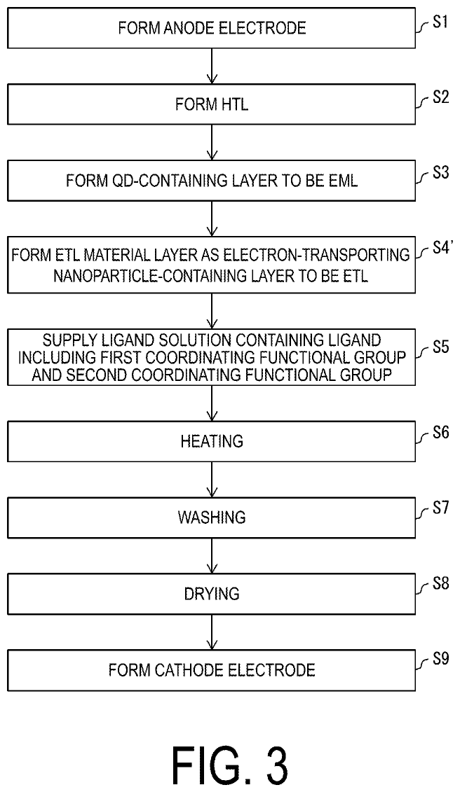

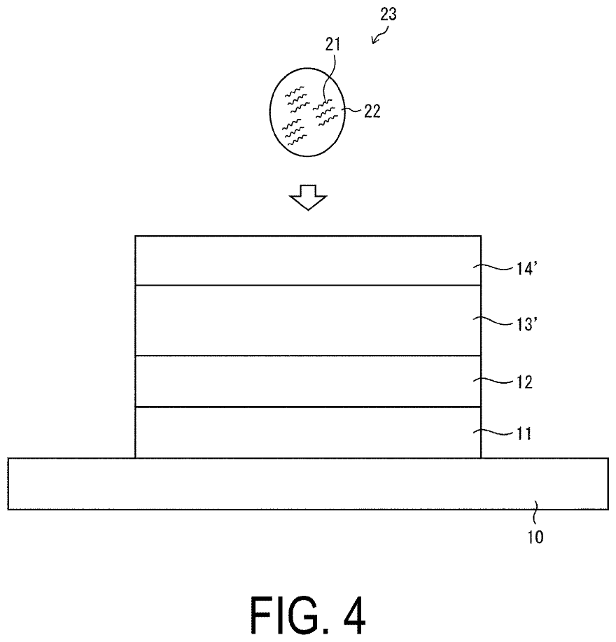

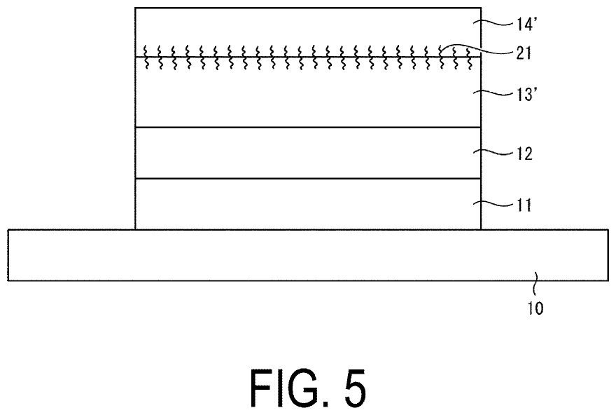

FIG. 2 is a flowchart illustrating an example of an overview of the manufacturing method for the light-emitting element 1 according to the present embodiment. FIG. 3 is a flowchart illustrating another example of an overview of the manufacturing method for the light-emitting element 1 according to the present embodiment. FIG. 4 is a cross-sectional view illustrating a ligand solution supplying process illustrated in S5 in FIG. 2 or FIG. 3. FIG. 5 is a cross-sectional view schematically illustrating the layered body (substrate 10 to electron-transporting nanoparticle-containing layer 14′ to be described below) after the ligand solution supplying process illustrated in the S5 in FIG. 2 or 3. In FIGS. 4 and 5, the QDs 131 and the nanoparticles 141 are not illustrated.

As illustrated in FIG. 2, in a manufacturing process for the light-emitting element 1 according to the present embodiment, first, as an example, for example, the anode electrode 11 is formed on the substrate 10 (step S1: anode electrode forming process). Subsequently, the HTL 12 is formed (step S2: HTL forming process). Next, as a layer 13′ containing the QDs 131 (hereinafter, referred to as a “QD-containing layer”) to be the EML 13, for example, a layer containing the QDs 131 and the ligand 25 is formed (step S3: QD-containing layer forming process, first nanoparticle-containing layer forming process). Next, the ETL material colloidal solution (ETL material dispersion liquid) is applied onto the QD-containing layer 13′ as an ETL material containing the nanoparticles 141. As a result, an ETL material colloidal solution layer (ETL material applied layer), which is, for example, a liquid-accompanying nanoparticle layer, is formed as a layer 14′ containing the nanoparticles 141 (hereinafter, referred to as “electron-transporting nanoparticle-containing layer”) to be the ETL 14 (step S4: electron-transporting nanoparticle-containing layer forming process, second nanoparticle containing layer forming process). Next, as illustrated in FIGS. 2 and 4, a ligand solution 23 containing the ligand 21 including the first coordinating functional group and the second coordinating functional group is supplied onto the electron-transporting nanoparticle-containing layer 14′ (step S5: ligand solution supplying process). Next, as illustrated in FIG. 2, the layered body (substrate 10 to electron-transporting nanoparticle-containing layer 14′) after the supply of the ligand solution 23 is heated (step S6: heating process), washed (step S7: washing process), and dried (step S8: drying process). As a result, the ETL 14 formed by the electron-transporting nanoparticle-containing layer 14′ is formed. In addition, ligand exchange in the QD-containing layer 13′ is completed, and the EML 13 formed by the QD-containing layer 13′ is formed. Subsequently, the cathode electrode 15 is formed (step S9: cathode electrode forming process).

Note that after formation of the cathode electrode 15 in step S9, the layered body (anode electrode 11 to cathode electrode 15) formed on the substrate 10 may be sealed with a sealing member. The sealing member may be a sealing film including an inorganic sealing layer and an organic sealing layer, or may be sealing glass. Hereinafter, each process described above will be described in greater detail.

For the formation of the anode electrode 11 and the cathode electrode 15 in step S1 and step S9, for example, sputtering, film evaporation, vacuum vapor deposition, physical vapor deposition (PVD), or the like is used. The anode electrode 11 or the cathode electrode 15 may be formed using a mask (not illustrated), or by forming the material of each electrode into a solid film and then patterning the film into a desired shape as necessary. For example, when the light-emitting element 1 is a part of a display device, the anode electrode 11 may be formed for each pixel by forming an anode electrode material (electrode material) into a solid film and then patterning the film.

For the formation of the HTL 12 in step S2, various known methods for forming the HTL can be used. For example, sputtering, vacuum vapor deposition, PVD, a spin coating method, an ink-jet method, or the like is used for the formation of the HTL 12.

The QD-containing layer 13′ can be formed by, for example, applying and drying a QD colloidal solution (QD dispersion liquid) containing the QDs 131 in step S3. A spin coating method can be used to apply the QD colloidal solution.

As the QD colloidal solutions, for example, colloidal solutions containing the QDs 131, a ligand having a coordinating functional group (adsorption group) for coordination (adsorption) to the QDs 131, and a solvent are used. As described above, for example, the ligand 25 is used as the ligand.

For example, commercially available QD colloidal solutions typically include a ligand. With the ligand coordinated to the surfaces of the QDs, mutual aggregation of the QDs can be suppressed. Therefore, a commercially available QD colloidal solution may be used as the QD colloidal solution. Therefore, the ligand 25 contained in the QD colloidal solution may be a ligand contained in a commercially available QD colloidal solution.

The solubility of the ligand alone is slightly different from the solubility of the ligand and the QDs 131 in a state where the ligand has coordinated to the QDs 131. Therefore, the solvent used in the QD colloidal solutions is not particularly limited as long as the solvent allows the QDs 131 alone, the ligand 25 alone, and the QDs 131 and the ligand 25 in a state where the ligand 25 has coordinated to the QDs 131 to dissolve therein.

Nanoparticles such as QDs are typically susceptible to degradation due to water. The QDs 131 alone, the ligand 25 alone, and the QDs 131 and the ligand 25 in a state where the ligand 25 has coordinated to the QDs 131 are dissolved in non-polar solvents (apolar solvents). Therefore, a non-polar solvent (apolar solvent) is preferably used as the solvent in the QD colloidal solution.

It should be noted that the concentration of the QDs 131, the concentration of the ligand, and the concentration of the ligand with respect to the QDs 131 in the QD colloidal solution may be set in a known manner, and are not particularly limited as long as a concentration or viscosity allowing the application is achieved. For example, the concentration of QDs in the case of using a spin coating method is generally set to from about 5 to 20 mg/mL in order to obtain a practical QD film thickness. However, the above example is merely an example, and the optimum concentration varies depending on the film formation method.

For example, heat drying such as baking can be used for drying the QD colloidal solution. The drying temperature (for example, baking temperature) may be appropriately set according to the type of the solvent so that the unnecessary solvent contained in the QD colloidal solution can be removed. Therefore, the drying temperature is not particularly limited, but is preferably in a range of from 60 to 120° C., for example. Thus, unnecessary solvents contained in the QD colloidal solution can be removed without causing thermal damage to the QDs 131. The drying time may be appropriately set according to the drying temperature so that the unnecessary solvent contained in the QD colloidal solution can be removed, and is not particularly limited.

As described above, the EML 13 according to the present embodiment is formed by supplying the ligand solution 23 to the QD-containing layer 13′ to exchange at least a part of the ligand 25 contained in the QD-containing layer 13′ with the ligand 21. The supply of the ligand solution 23 will be described later.

As described above, the ETL material colloidal solution layer as the electron-transporting nanoparticle-containing layer 14′ can be formed by applying the ETL material colloidal solution (ETL material dispersion liquid) containing the nanoparticles 141. As described above, the ETL 14 is preferably thinner than the EML 13. Therefore, in the electron-transporting nanoparticle-containing layer forming process (second nanoparticle containing layer forming process), it is desirable to form the electron-transporting nanoparticle-containing layer 14′ with the ETL 14 being thinner than the EML 13. In the disclosure, the fact that the second nanoparticle layer is thinner than the first nanoparticle layer means that the second nanoparticle containing layer is formed to be thinner than the first nanoparticle layer in the second nanoparticle containing layer forming process. A spin coating method can be used to apply the ETL material colloidal solution.

As the ETL material colloidal solution, for example, a colloidal solution containing the nanoparticles 141 and a solvent is used.

The nanoparticles 141 such as ZnO are dissolved (dispersed) in a polar solvent such as water or ethanol unless a special treatment is performed. Therefore, for the sake of solubility (dispersibility) of the nanoparticles 141, it is desirable to use a polar solvent as the solvent of the ETL material colloidal solution. In the disclosure, dissolving nanoparticles in a solvent means dispersing the nanoparticles in the solvent until the nanoparticles become colloidal.

In addition, in order to improve dispersibility, the ETL material colloidal solution may further include a monofunctional ligand having one coordinating functional group (adsorption group) for coordination (adsorption) to the nanoparticles 141. As described above, examples of the ligand include the ligand 25 (strictly, the ligand exemplified as the ligand 25).

It should be noted that the concentration of the nanoparticles 141, the concentration of the ligand, and the concentration of the ligand with respect to the nanoparticles 141 in the ETL material colloidal solution may be set in a known manner, and are not particularly limited as long as a concentration or viscosity allowing the application is achieved.

FIG. 2 illustrates an example in which the electron-transporting nanoparticle-containing layer 14′ is an ETL material colloidal solution layer as described above. However, the present embodiment is not limited to this example.

In an example such as that where, upon forming a plurality of the light-emitting elements 1 on a motherboard, the ETL 14 common to the plurality of light-emitting elements 1 is formed, the ETL material colloidal solution layer may be dried once when the ETL 14 does not need to be patterned in the light-emitting elements 1.

In this case, as illustrated in FIG. 3, after step S3, the ETL material colloidal solution as an ETL material containing the nanoparticles 141 is applied onto the QD-containing layer 13′ and dried. Thus, step S4′ (electron-transporting nanoparticle-containing layer forming process, second nanoparticle containing layer forming process) of forming a solid ETL material layer as the electron-transporting nanoparticle-containing layer 14′ is performed instead of step S4. Thereafter, step S5 is performed as in FIG. 2. As described above, the electron-transporting nanoparticle-containing layer 14′ may be a solid ETL material layer obtained by drying the ETL material colloidal solution layer, or the ligand solution 23 may be supplied onto the ETL material layer.

Still, as illustrated in FIG. 2, the drying process for the ETL material colloidal solution layer before supplying the ligand solution 23 can be omitted by supplying the ligand solution 23 to perform the ligand exchange after applying the ETL material colloidal solution and before drying the ETL material colloidal solution.

Next, the supply of the ligand solution 23 will be described. Hereinafter, for convenience of description, a case where the ETL material colloidal solution does not contain a ligand will be described as an example.

As illustrated in FIG. 4, the ligand solution 23 used in step S5 contain the ligand 21 and a solvent 22.

In the present embodiment, in the QD-containing layer 13′, at least the ligand 25 at the interface with the electron-transporting nanoparticle-containing layer 14′ is exchanged with the ligand 21. As a result, in the EML 13, at least the ligand 25 at the interface with the ETL 14 is exchanged with the ligand 21. At this time, when a solvent in which the QDs 131 in the QD-containing layer 13′ dissolve is used as the solvent 22 of the ligand solution 23, not only ligand exchange but also dissolution of the QD-containing layer 13′ occurs. Therefore, in the present embodiment, as described above, in order to prevent the QD-containing layer 13′, which is the lower layer side nanoparticle layer among the nanoparticle layers layered adjacent to each other, from being dissolved, a solvent in which the QDs 131 of the QD-containing layer 13′ do not dissolve is used as the solvent 22 of the ligand solution 23. Therefore, to prevent the QD-containing layer 13′ from being dissolved, a solvent is used, as the solvent 22, in which the QDs 131 alone, the ligand 25 alone, and the QDs 131 and the ligand 25, which are in a state where the ligand 25 has coordinated to the QDs 131, do not dissolve, and the ligand 21 can dissolve.

As described above, nanoparticles such as QDs are typically susceptible to degradation due to water. The QDs 131 alone, the ligand 25 alone, and the QDs 131 and the ligand 25 in a state where the ligand 25 has coordinated to the QDs 131 are dissolved in non-polar solvents (apolar solvents).

Therefore, when the ligand exchange in the QD-containing layer 13′ is performed as described above, a polar solvent is generally used as the solvent 22 regardless of whether the ligand 21 is a polar molecule having the above-described polar bonding group or a non-polar molecule not having the above-described polar bonding group.

Still, as described above, the nanoparticles 141 such as ZnO are dissolved (dispersed) in a polar solvent unless a special treatment is performed. Therefore, in the present embodiment, as an example, for example, as illustrated in FIG. 2, before the ETL material colloidal solution is dried, the ligand solution 23 is supplied to cause the ligand exchange.

Whichever of the flows illustrated in FIGS. 2 and 3 is employed, as the solvent 22 of the ligand solution 23, a solvent in which the lower layer side nanoparticle-containing layer (the QD-containing layer 13′ in the present embodiment), which is to be the lower layer side nanoparticle layer among the adjacently layered nanoparticle layers, does not dissolve is used.

Examples of a method of supplying the ligand solution 23 in step S5 (ligand solution supplying process) include a method of dispersing the ligand solution 23. The ligand solution 23 may be sprayed to be dispersed in a form of mist, for example, or may be dropped to be dispersed in a form of drops. For dispersing (supplying) the ligand solution 23, for example, an ink-jet method may be used, or a mist spraying device may be used.

In addition, for example, when the ligand solution 23 is supplied onto the solid layer as in the case where the ligand solution 23 is supplied onto the ETL material layer, the supplied ligand solution 23 may be applied onto the surface of the solid layer by, for example, spin coating after supplying (for example, dispersing) the ligand solution 23 onto the solid layer. Thus, the ligand solution 23 can be uniformly applied onto the solid layer.

As described above, when the ligand solution 23 is supplied onto the electron-transporting nanoparticle-containing layer 14′ (for example, the ETL material colloidal solution layer or the ETL material layer), the ligand solution 23 permeates from the electron-transporting nanoparticle-containing layer 14′ as the upper layer toward the QD-containing layer 13′ as the lower layer. As a result, the ligand 21 coordinates to at least part of the nanoparticles 141 of the electron-transporting nanoparticle-containing layer 14′, and the ligand 25 having coordinated to the QDs 131 of the QD-containing layer 13′ is exchanged (substituted) with the ligand 21. The QDs 131 and the nanoparticles 141 are immobilized (bonded) via the ligands 21 at the interface between the QD-containing layer 13′ and the electron-transporting nanoparticle-containing layer 14′. At this time, in the QD-containing layer 13′, a portion closer to the interface with the electron-transporting nanoparticle-containing layer 14′ is substituted by the ligand 21 at a higher concentration, meaning that the exchange rate with the ligand 21 is lower at a portion farther from the interface. Therefore, for example, depending on the supply amount, viscosity, concentration, and the like of the ligand solution 23, the ligand 25 maintains a higher concentration state and remains in the QD-containing layer 13′ in a portion farther from the interface with the electron-transporting nanoparticle-containing layer 14′ (in other words, the upper surface of the QD-containing layer 13′). For example, by adjusting the supply amount, viscosity, concentration, and the like of the ligand solution 23, it is also possible to completely exchange the ligand 25 with the ligand 21.

When the electron-transporting nanoparticle-containing layer 14′ contains the ligand 25, the ligand 25 having coordinated to the nanoparticles 141 is similarly exchanged with the ligand 21. At this time, a portion closer to the upper surface of the electron-transporting nanoparticle-containing layer 14′ is substituted by the ligand 21 at a higher concentration, meaning that the exchange rate with the ligand 21 is lower at a portion farther from the upper surface of the electron-transporting nanoparticle-containing layer 14′. Therefore, for example, depending on the supply amount, viscosity, concentration, and the like of the ligand solution 23, the ligand 25 maintains a higher concentration state and remains in a portion farther from the upper surface of the electron-transporting nanoparticle-containing layer 14′. For example, by adjusting the supply amount, viscosity, concentration, and the like of the ligand solution 23, it is also possible to completely exchange the ligand 25 of the electron-transporting nanoparticle-containing layer 14′ or the ligand 25 of the electron-transporting nanoparticle-containing layer 14′ and the QD-containing layer 13′ with the ligand 21.

In any case, in the present embodiment, it suffices if the QDs 131 and the nanoparticles 141 are finally immobilized (bonded) via the ligand 21 at the interface between the EML 13 and the ETL 14. This makes it possible to suppress or prevent electromigration at the interface. Therefore, the ligand 21 may coordinate to the QDs 131 of the QD-containing layer 13′ over the entire layering direction, but this is not an essential configuration. In addition, the ligand 25 of the electron-transporting nanoparticle-containing layer 14′ or the entire ligand 25 of the electron-transporting nanoparticle-containing layer 14′ and the QD-containing layer 13′ may be exchanged with the ligand 21, but this is not an essential configuration.

The concentration of the ligand 21 contained in the ligand solution 23 is not particularly limited, but is preferably in the range of from 0.01 mol/L to 2.0 mol/L.

In order to perform ligand exchange, the ligand 25 having coordinated to the nanoparticles (for example, QDs 131) of the nanoparticle layer before ligand exchange needs to be dissolved (dispersed) in the ligand solution 23. Therefore, the concentration of the ligand 21 in the ligand solution 23 is preferably within the above range for the sake of the balance between the supply of the ligand 21 and the dissolution of the ligand 25 in the ligand solution 23.

The supply amount of the ligand 21 varies depending on, for example, the type and layer thickness of each of the first nanoparticle containing layer and the second nanoparticle containing layer to which the ligand 21 is supplied, the method of adding the ligand 21, the size of the light-emitting region, and the like. The supply amount of the ligand solution 23 in the ligand exchange process (step S5) is not particularly limited as long as the amount is set to an amount with which the ligand 21 contained in the ligand solution 23 can reach at least the interface between the first nanoparticles and the second nanoparticles so that the ligand 21 can bond the first nanoparticles and the second nanoparticles at least at the interface between the first nanoparticles and the second nanoparticles.

The viscosity of the ligand solution 23 can be appropriately adjusted to a desired range by adjusting the temperature, pressure, and the like at the time of applying the ligand solution 23. For this reason, the viscosity of the ligand solution 23 is not particularly limited, but is preferably within a range of from 0.5 to 500 mPa·s. Thus, permeation unevenness of the ligand solution 23 can be reduced.

The viscosity of the ligand solution 23 is more preferably in a range of from 1 to 100 mPa·s. Thus, permeation unevenness of the ligand solution 23 can be further reduced.

The viscosity can be measured using a known rotational viscometer, B-type viscometer, or the like. In the present embodiment, a value measured in accordance with “JIS Z 8803: 2011 Methods for viscosity measurement of liquid” using a vibration type viscometer VM-10A-L manufactured by CBC Materials Co., Ltd. is provided.

As described above, in order to bond the QDs 131 and the nanoparticles 141 at the interface between the QD-containing layer 13′ and the electron-transporting nanoparticle-containing layer 14′, it suffices if the ligand 25 having coordinated to the QDs 131 at the interface is exchanged with the ligand 21. In order to exchange the ligand 25 having coordinated to the QDs 131 at the interface with the ligand 21, it is only necessary to supply the ligand solution 23 onto the electron-transporting nanoparticle-containing layer 14′ and cause the ligand solution 23 to permeate from the electron-transporting nanoparticle-containing layer 14′ to the QD-containing layer 13′, meaning that heating is not required in particular. According to the layer thickness of the ETL 14 formed by the electron-transporting nanoparticle-containing layer 14′, the ligand solution 23 permeates to the interface immediately after being supplied onto the electron-transporting nanoparticle-containing layer 14′. Therefore, management and control of the time required for ligand exchange are not particularly required. If necessary, heating may be performed as described in step S6 to complete the ligand exchange, or a holding time for the permeation of the ligand solution 23 may be provided.

As illustrated in FIG. 5, the QDs 131 and the nanoparticles 141 adjacent to each other at the interface between the QD-containing layer 13′ and the electron-transporting nanoparticle-containing layer 14′ are bonded to each other by the same ligand 21, as a result of causing the ligand solution 23 to permeate from the electron-transporting nanoparticle-containing layer 14′ toward the QD-containing layer 13′ as described above. Thus, as illustrated in FIG. 1, the QDs 131 and the nanoparticles 141 adjacent to each other at the interface between the EML 13 and the ETL 14 are bonded to each other by the same ligand 21.

Then, as illustrated in step S7 in FIG. 2, unnecessary ligand is removed by washing using a rinse liquid.

The washing method is not particularly limited, and various known methods can be employed. For example, as described in a specific example below, after a sufficient amount of rinse liquid has been supplied by dripping or the like, the supplied rinse liquid may be applied by, for example, a spin coating method or the like.

Here, the sufficient amount means an amount sufficient for the substrate size of the support body to be used. As an example, when the substrate size of the support body is 25 mm×25 mm×0.7 mm, 200 μL of the rinse liquid is used, for example.

When the ligand 21 coordinates to the QDs 131 as a result of the ligand exchange, the QDs 131 to which the ligand 21 has coordinated are insolubilized so as not to be dissolved in any solvents. Similarly, the nanoparticles 141 to which the ligands 21 have coordinated are also insolubilized so as not to be dissolved in any solvent. Therefore, the solvent used as the rinse liquid is not particularly limited as long as the solvent allows the ligand 25 having coordinated to the QDs 131 (or the QDs 131 and the nanoparticles 141) that is an unnecessary ligand as well as the excess ligands 21 and the ligand 25 not coordinating to the QDs 131 and the nanoparticles 141 to dissolve therein.

As described above, nanoparticles such as QDs are typically susceptible to degradation due to water. The QDs 131 alone, the ligand 25 alone, and the QDs 131 and the ligand 25 in a state where the ligand 25 has coordinated to the QDs 131 are dissolved in non-polar solvents (apolar solvents). For this reason, a non-polar solvent (apolar solvent) is generally used for the rinse liquid, as in the case of the solvent in the QD colloidal solution.

As the non-polar solvent (for example, non-polar solvents used as the solvent in the rinse liquid and the QD colloidal solution), for example, a solvent having a Hildebrand solubility parameter (δ value) of 9.3 or less is preferable, and a solvent having the δ value of 7.3 or more and 9.3 or less is more preferable. As the non-polar solvent, for example, a solvent having a relative dielectric constant (Fr value), measured at from around 20 to 25° C., of 6.02 or less is preferable, and a solvent having the Fr value of 1.89 or more and 6.02 or less is more preferable. The non-polar solvent does not degrade the nanoparticles such as the QDs 131 and does not dissolve the nanoparticles to which the ligands 21 have coordinated. Therefore, the solvents described above are preferably used as the non-polar solvent.

The non-polar solvent is not particularly limited, and examples thereof include at least one solvent selected from the group consisting of toluene, hexane, octane, and chlorobenzene. Toluene, hexane, and octane are non-polar solvents that have the δ value of 7.3 or more and 9.3 or less and the Fr value of 1.89 or more and 6.02 or less, and have particularly high solubility of the QDs 131 to which the ligand 25 has coordinated, for example, and are easily available. Chlorobenzene is a non-polar solvent that has the Fr value of 6.02 or less, and has particularly high solubility of the QDs 131 to which the ligand 25 has coordinated, for example, and is easily available. Therefore, the solvents described above are particularly preferably used as the non-polar solvent.

As the polar solvent (for example, polar solvents used as the solvent in the ETL material colloidal solution and the solvent 22 in the ligand solution 23), for example, a solvent having the δ value of more than 9.3 is preferable, and a solvent having the δ value of more than 9.3 and 12.3 or less is more preferable. The δ value of the polar solvent is more preferably 10 or more. Therefore, the polar solvent is still more preferably a solvent having the δ value of 10 or more and 12.3 or less. As the polar solvent, for example, a solvent having the εᵣ value of more than 6.02 is preferable, and a solvent having the Fr value of more than 6.02 and 46.7 or less is more preferable.

The polar solvent is not particularly limited, and examples thereof include at least one solvent selected from the group consisting of propylene glycol monomethyl ether acetate (PGMEA), methanol, ethanol, acetonitrile, and ethylene glycol. At least one solvent selected from the group consisting of PGMEA, methanol, ethanol, acetonitrile, and ethylene glycol is a polar solvent that has a solubility parameter of 10 or more, is easily available, and has a small number of molecules.

Therefore, when the polar solvent is used as the solvent 22, for example, the ligand 21 can be uniformly dissolved when the ligand 21 is polar molecules of course, and also in the case where the ligand 21 is non-polar molecules.

In step S8, unnecessary solvents adhering to the layered body (the substrate 10 to the electron-transporting nanoparticle-containing layer 14′ in the present embodiment) after step S7 are removed by drying. For example, heat drying such as baking can be used for the drying. The drying temperature (for example, baking temperature) and the drying time may be appropriately set so that the unnecessary solvent can be removed, and are not particularly limited.

### Specific Example of Manufacturing Method for Light-Emitting Element 1

Hereinafter, a specific example of a manufacturing method for the light-emitting element 1 will be described with emphasis on a method of forming the EML 13 and the ETL 14. However, the specific example below is an example of the manufacturing method for the light-emitting element 1 as described above, and the present embodiment is not limited to this.

In this specific example, for example, tin-doped indium oxide (ITO) was first patterned as the anode electrode 11 on a glass substrate as the substrate 10.

Next, poly(N-vinylcarbazole) (PVK) dissolved in chlorobenzene (CBZ) was spin-coated on the glass substrate on which the ITO was patterned, and annealed to form a PVK film having a layer thickness of 20 nm as the HTL 12.

Next, the QD colloidal solution was dropped on the PVK film and spin-coated at 3000 rpm to form a film, which was then heated (annealed) at 110° C. for 15 minutes to remove the solvent and dry the film. As the QD colloidal solution, a QD colloidal solution obtained by dispersing QD (QDs 131) having the surface modified with octanethiol (CH₃(CH₂)₇SH, ligand 25) in hexane at a ligand concentration of 20 wt % and a QD concentration of 20 mg/mL was used. As the QD, a red QD that includes a core made of CdS and having a particle size of 1 nm and a shell made of ZnSe, and has an emission peak wavelength at 630 nm was used. As a result, a QD film having a layer thickness of 20 nm was formed as the QD-containing layer 13′ to be the EML 13.

Next, on the QD film, an ETL material colloidal solution obtained by dispersing ZnO nanoparticles (nanoparticles 141) in ethanol at a ratio of 2.5 wt % was dropped and spin-coated at 2000 rpm to form a film. In this example, after forming the film of the ETL material colloidal solution, the film was heated (annealed) at 80° C. for 30 minutes to remove the solvent and dry the film. As a result, a ZnO nanoparticle film having a layer thickness of 50 nm was formed as the electron-transporting nanoparticle-containing layer 14′ (solid ETL material layer) to be the ETL 14.

As described above, in order to facilitate the permeation of the ligand solution 23 containing the ligand 21 to the interface between the ZnO nanoparticle film and the QD layer, the ZnO nanoparticle film is preferably thinner than the QD layer. When the thickness of the ETL 14 is smaller than the above-described thickness, the probability of ligand exchange is likely to increase. However, when the thickness of the ETL 14 is about 50 nm or less, the ligand solution 23 can sufficiently permeate even if the ETL 14 is thicker than the EML 13.

Next, 200 μL of the ligand solution 23 obtained by dissolving 2,2′-(ethylenedioxy)diethanethiol (HSCH₂CH₂OCH₂CH₂OCH₂CH₂SH, ligand 21) in acetonitrile (solvent 22) at a ratio of 0.1 mol/L was dropped on the ZnO nanoparticle film. After 10 seconds after the ligand solution 23 was dropped, the dropped ligand solution 23 was spin-coated at 2000 rpm, and then heated (annealed) at 100° C. for 10 minutes. As a result, a part of the ligand 25 coordinating to the QDs was exchanged (substituted) with the ligand 21, and the QDs and the ZnO nanoparticles at the interface between the QD film and the ZnO nanoparticle film were bonded by the ligand 21.

Then, a sufficient amount of toluene, serving as a rinse liquid, was dropped on the ZnO nanoparticle film and spin-coated at 3000 rpm. As a result, unnecessary ligands were washed away.

Then, the film was heated (annealed) at 110° C. for 15 minutes to remove the solvent and dry the film. Thus, the ETL 14 made of the ZnO nanoparticle film was formed, and the EML 13 made of the QD film was formed.

Then, on the ZnO nanoparticle film, an aluminum (Al) electrode having a layer thickness of 100 nm was formed into a film as the cathode electrode 15 by vacuum vapor deposition using a patterning mask.

Thereafter, sealing glass coated with an ultraviolet (UV) curing resin was placed so as to cover the active area for sealing. In this manner, the light-emitting element 1 according to the present embodiment was obtained.

In the above specific example, as an example, the case where the electron-transporting nanoparticle-containing layer 14′ is a solid ETL material layer obtained by forming a film of the ETL material colloidal solution and then drying the film is described as an example. Alternatively, as described above, the electron-transporting nanoparticle-containing layer 14′ may be an ETL material colloidal solution layer, and the ligand solution 23 may be supplied without drying the ETL material colloidal solution after the film formation.

In the above-described specific examples, as an example, the case where the QDs 131 are red QDs that emit red light has been described as an example. However, it is a matter of course that the QDs 131 may be green QDs that emit green light or blue QDs that emit blue light. In addition, materials, dimensions, and other various conditions unrelated to QD can also be appropriately changed based on the above description.

In the above-described specific examples, the case where the light-emitting element 1 is a bottom-emission light-emitting element in which light emitted from the EML 13 is extracted from the substrate 10 side is described as an example. However, the light-emitting element 1 may be a top-emission display device in which light is extracted from a surface opposite to the substrate 10 (upper surface side, specifically, the sealing glass side).

As described above, according to the above-described method, it is possible to manufacture the light-emitting element 1 in which the QDs 131 and the nanoparticles 141 adjacent to each other at the interface between the EML 13 and the ETL 14 are bonded to each other by the same ligand 21.

The bonding between the QDs 131 and the nanoparticles 141 adjacent to each other at the interface between the EML 13 and the ETL 14 by the same ligand 21 can be confirmed by performing, on an element cross section, analysis on a layered structure using scanning electron microscope (SEM), transmission electron microscope (TEM) or the like, or composition analysis using energy dispersive X-ray spectroscopy (EDX), secondary ion mass spectrometry (SIMS), or the like.

Depending on the ligand to coordinate, whether the coordination is successfully achieved can be confirmed by, for example, measurement using Fourier transform infrared spectroscopy (FT-IR) (hereinafter, referred to as “FT-IR measurement”). For example, when the ligand to be coordinate to the QDs 131 or the nanoparticles 141 has a C(═O)OH group or a —P(═O) group as the coordinating functional group, vibrations observed in the FT-IR measurement slightly differ between the uncoordinated state and the coordinated state, resulting in a shift in detection peak.

In addition, the coordination of the ligand 21 can also be confirmed when, after the ligand exchange, the peak of the ligand 25 before the exchange disappears, and only the peak of the ligand 21 after the exchange remains as a result of the exchange.

Further, when at least one of the ligand 25 and the ligand 21 has a functional group exhibiting a specific peak in addition to the coordinating functional group, the coordination can be confirmed by the detected amount thereof. Examples of such a functional group include an ether group, an ester group, and a C═C bond of oleic acid. In particular, the ligand exchange can be confirmed, when a specific peak existing before the ligand exchange disappears after the ligand exchange, or when a new specific peak is detected after the ligand exchange.

### First Modified Example

In the present embodiment, as described above, the case where the polar solvent is used as the solvent 22 of the ligand solution 23 to prevent the dissolution of the QD-containing layer 13′ as the lower layer side nanoparticle-containing layer is described as an example. However, the present embodiment is not limited to this example.

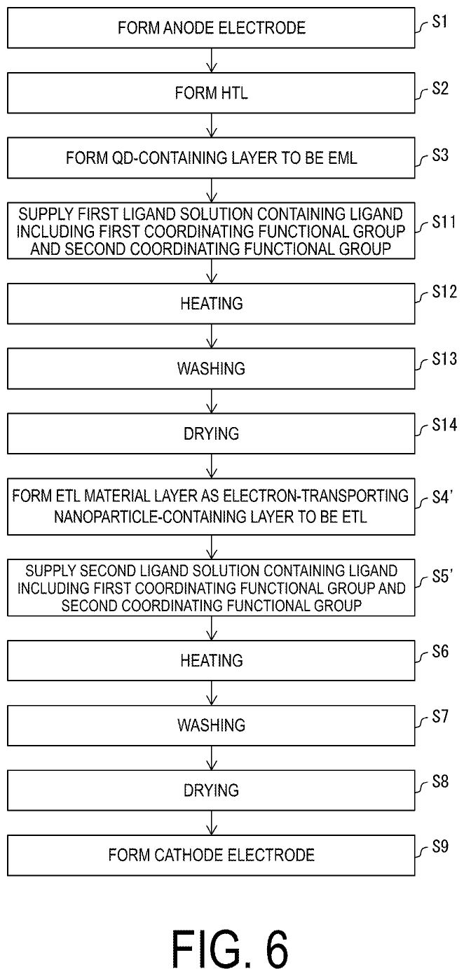

FIG. 6 is a flowchart illustrating another example of an overview of the manufacturing method for the light-emitting element 1 according to the present embodiment.

In the manufacturing process for the light-emitting element 1 illustrated in FIG. 6, first, the anode electrode 11 is formed on the substrate 10 (step S1: anode electrode forming process). Subsequently, the HTL 12 is formed (step S2: HTL forming process). Next, as the QD-containing layer 13′ to be the EML 13, for example, a layer containing the QDs 131 and the ligand 25 is formed (step S3: QD-containing layer forming process, first nanoparticle containing layer forming process). The processes up to this point are the same as the steps S1 to S3 illustrated in FIG. 2 or FIG. 3. In the present example, next, a first ligand solution containing the ligand 21 including the first coordinating functional group and the second coordinating functional group is supplied onto the QD-containing layer 13′ (step S11: first ligand solution supplying process). Next, as illustrated in FIG. 6, the layered body (substrate 10 to QD-containing layer 13′) after the supply of the first ligand solution is heated (step S12: heating process), washed (step S13: washing process), and dried (step S14: drying process). Thus, the ligand 25 in the QD-containing layer 13′ is exchanged (substituted) with the ligand 21 to form, for example, a layer containing the QDs 131 and the ligand 21 as the ligand-exchanged QD-containing layer 13′ to be the EML 13. Next, the ETL material colloidal solution (ETL material dispersion liquid) is applied and dried on the QD-containing layer 13′, after the ligand exchange, containing the QDs 131 and the ligand 21, as an ETL material containing the nanoparticles 141. Thus, a solid ETL material layer is formed as the electron-transporting nanoparticle-containing layer 14′ (step S4′: electron-transporting nanoparticle-containing layer forming process, second nanoparticle containing layer forming process). Next, a second ligand solution containing the ligand 21 including the first coordinating functional group and the second coordinating functional group is supplied onto the electron-transporting nanoparticle-containing layer 14′ (step S5′: second ligand solution supplying process (ligand solution supplying process)). Next, the layered body (substrate 10 to electron-transporting nanoparticle-containing layer 14′) after the supply of the second ligand solution is heated (step S6: heating process), washed (step S7: washing process), and dried (step S8: drying process). As a result, the ETL 14 formed by the electron-transporting nanoparticle-containing layer 14′ is formed. Furthermore, the EML 13 formed by the QD-containing layer 13′ after the ligand exchange is formed. Subsequently, the cathode electrode 15 is formed (step S9: cathode electrode forming process). Note that, also in the present modification, after formation of the cathode electrode 15 in step S9, the layered body (anode electrode 11 to cathode electrode 15) formed on the substrate 10 may be sealed with a sealing member.

As described above, the nanoparticles 141 such as ZnO are dissolved (dispersed) in a polar solvent such as water or ethanol unless a special treatment is performed. Therefore, in the present modification, non-polar solvent (apolar solvent) is used for the solvent of the second ligand solutions in step S5′ so that the solid ETL material layer as the electron-transporting nanoparticle-containing layer 14′ is not dissolved.

Still, the QDs 131 alone, the ligand 25 alone, and the QDs 131 and the ligand 25 in a state where the ligand 25 has coordinated to the QDs 131 are dissolved in non-polar solvents. Therefore, in the case where the QD-containing layer 13′ is a layer containing the QDs 131 and the ligand 25 which is not subjected to ligand exchange with the ligand 21, the QD-containing layer 13′ is dissolved when the second ligand solution containing a non-polar solvent is supplied onto the electron-transporting nanoparticle-containing layer 14′. Therefore, in the present modification, before the electron-transporting nanoparticle-containing layer 14′ is formed in step S4′, steps S11 to S14 are performed to exchange (substitute) the ligand 25 in the QD-containing layer 13′ with the ligand 21. This allows the ligand 21 to coordinate only to the QDs 131 prior to the nanoparticles 141.

When the ligand 21 coordinates to the QDs 131 as a result of the ligand exchange, the QDs 131 to which the ligand 21 has coordinated are insolubilized so as not to be dissolved in any solvents. Therefore, even when the second ligand solution is supplied onto the ETL material layer after the formation of the ETL material layer, the QD-containing layer 13′ is not dissolved.

The same or a similar ligand solution as the ligand solution 23 is used as the first ligand solution used for the ligand exchange of the QDs 131 in step S11. The concentration of the ligand 21 contained in the first ligand solution can be set in the same manner as the concentration of the ligand 21 contained in the ligand solution 23. The viscosity of the first ligand solution can be set in the same manner as the viscosity of the ligand solution 23.

In the present modification, the content ratio between the QDs 131 and the ligand 21 in the EML 13 (QDs 131: ligand 21) is not particularly limited, but is preferably in a range of from 2:0.25 to 2:6, and more preferably in the range of from 2:1 to 2:4 in terms of weight ratio. With this configuration, the EML 13 can be formed that has the plurality of QDs 131 bonded to each other via the ligand 21, and features high liquid resistance to polar solvents and non-polar solvents and suppressed deterioration at the time of pattern forming. In general, the molecular skeleton of a ligand is mainly composed of an organic substance, and thus the ligand often exhibits insulating properties. Therefore, for the sake of carrier injection in the light-emission characteristics of the light-emitting element 1, it is preferable for the EML 13 to not contain an excessive amount of ligand. Therefore, it is desirable that the content ratio be within the range described above. The amount of the ligand 21 supplied in step S11 varies depending on, for example, the composition and layer thickness of the QD-containing layer 13′ to which the ligand 21 is supplied, the method of adding the ligand 21, the size of the light-emitting region, the processing time of step S11, and the like. However, since the amount of the ligand 21 supplied per QD 131 is sufficient regardless of the above-mentioned conditions, the amount of the ligand 21 actually coordinating to the QDs 131 tends to depend on the concentration of the ligand 21 contained in the first ligand solution. In step S13, as will be described below, the excess ligand 21 not coordinating to the QDs 131 is removed by a rinse liquid (first rinse liquid). In step S11, the ligand 21 in the amount exceeding the above-described content ratio of the QDs 131 and the ligand 21 in the EML 13 is supplied with respect to the QDs 131, so that the content ratio of the QDs 131 and the ligand 21 in the EML 13 finally falls within the above-described range by removing the excess ligand 21 in step S13. Therefore, by setting the concentration of the ligand 21 in the first ligand solution as described above, for example, the content ratio between the QDs 131 and the ligand 21 in the desirable range described above can be obtained in the QD-containing layer 13′ after the ligand exchange and the finally formed EML 13. With this configuration, as described above, the EML 13 can be formed that has the plurality of QDs 131 bonded to each other via the ligand 21, and features high liquid resistance to polar solvents and non-polar solvents and suppressed deterioration at the time of pattern forming.

As a method of supplying the first ligand solution in step S11, the same or a similar method as the method of supplying the ligand solution 23 in step S5 can be used. When the first ligand solution is supplied onto the QD-containing layer 13′, the first ligand solution can be uniformly applied onto the QD-containing layer 13′ by supplying (for example, dispersing) the first ligand solution onto the QD-containing layer 13′ and then applying the supplied first ligand solution on the surface of the QD-containing layer 13′ by, for example, spin coating.

The heating process in step S12 can be performed in the same manner as the heating process in step S6. The washing process in step S13 can be performed in the same manner as the washing process in step S7. The drying process in step S14 can be performed in the same manner as the drying process in step S8.

As described above, the QDs 131 to which the ligand 21 has coordinated are insolubilized so as not to dissolve in any solvent. Therefore, as the solvent used as the rinse liquid (first rinse liquid) used in step S13, a solvent dissolving the ligand 25 having coordinated to the QDs 131 as unnecessary ligand and dissolving the excess ligands 21 not coordinating to the QDs 131 is used. Thus, a non-polar solvent is generally used for the first rinse liquid, as in the case of the solvent in the QD colloidal solution.

On the other hand, for the second ligand solution used in step S5′, the non-polar solvent as described above is used as a solvent not dissolving an upper layer side nanoparticle-containing layer (in the present embodiment, the ETL material layer as the electron-transporting nanoparticle-containing layer 14′) to be the upper layer side nanoparticle layer among the adjacently layered nanoparticle layers. As described above, at the point of step S5′, the QD-containing layer 13′ as a lower layer side nanoparticle-containing layer is no longer dissolved by the non-polar solvent.

As the second ligand solution, the same or a similar ligand solution as the ligand solution 23 is used except that a non-polar solvent is used as the solvent 22 instead of the polar solvent. The concentration of the ligand 21 contained in the second ligand solution can be set in the same manner as the concentration of the ligand 21 contained in the ligand solution 23. The viscosity of the second ligand solution can be set in the same manner as the viscosity of the ligand solution 23.

The amount of the ligand 21 supplied in the second ligand exchange process (step S5′) varies depending on, for example, the composition and layer thickness of the upper layer side nanoparticle-containing layer to which the ligand 21 is supplied, the method of adding the ligand 21, the size of the light-emitting region, and the like. The supply amount of the second ligand solution in the second ligand exchange process (step S5′) is not particularly limited as long as the amount is set to an amount with which the ligand 21 in the second ligand solution can reach the interface between the electron-transporting nanoparticle-containing layer 14′ and the QD-containing layer 13′ after the ligand exchange and bond the nanoparticles 141 and the QDs 131 at the interface.

As a method of supplying the second ligand solution in step S5′, the same or a similar method as the method of supplying the ligand solution 23 in step S5 can be used. When the second ligand solution is supplied onto the ETL material layer, the second ligand solution can be uniformly applied on the ETL material layer by supplying (e.g., dispersing) the second ligand solution onto the ETL material layer and then applying the supplied second ligand solution on the surface of the ETL material layer by, for example, spin coating.

When the second ligand solution is supplied onto the ETL material layer, the ligand 21 coordinates to at least part of the nanoparticles 141 of the ETL material layer, and the ligand 21 further coordinates to at least part of the QDs 131 of the QD-containing layer 13′. The QDs 131 and the nanoparticles 141 are immobilized (bonded) via the ligands 21 at the interface between the QD-containing layer 13′ and the electron-transporting nanoparticle-containing layer 14′.

The heating process in step S6 can be performed in the same manner as the heating process in step S6 illustrated in FIGS. 2 and 3. The washing process in step S7 can be performed in the same manner as the washing process in step S7 illustrated in FIGS. 2 and 3.

The nanoparticles 141 to which the ligand 21 has coordinated is insolubilized so as not to be dissolved in any solvents, as in the case of the QDs 131 to which the ligand 21 has coordinated. Therefore, as the solvent used as the rinse liquid (second rinse liquid) used in step S8, a solvent dissolving the ligand 25 having coordinated to the nanoparticles 141 as unnecessary ligand and dissolving the excess ligands 21 not coordinating to the nanoparticles 141 is used. Thus, a polar solvent is generally used for the second rinse liquid, as in the case of the solvent in the ETL material colloidal solution. However, as described above, nanoparticles such as QDs are susceptible to degradation due to water. Thus, a polar solvent other than water is preferably used for the polar solvent.

As the polar solvent and the non-polar solvent used in the present modification example, the polar solvent and the non-polar solvent described above in the present embodiment are preferably used.

### Second Modified Example

In the example case described above in the present embodiment, the ligand 25 alone, and the QDs 131 and the ligand 25 in a state where the ligand 25 has coordinated to the QDs 131 are dissolved in non-polar solvents (apolar solvents). However, the ligand 25, which is a monofunctional ligand, and the QDs 131 and the ligand 25 in a state where the ligand 25 has coordinated to the nanoparticle are dissolved (dispersed) in solvents having a polarity whose magnitude is corresponding to the magnitude of the polarity of the terminal group of the ligand 25.

Therefore, when a monofunctional ligand having a polar bonding group is used as the ligand 25, the QD-containing layer 13′ and the electron-transporting nanoparticle-containing layer 14′ before the ligand exchange dissolve in a polar solvent. Therefore, in the present modification, a non-polar solvent is used for the ligand solution so that the QD-containing layer 13′ and the electron-transporting nanoparticle-containing layer 14′ do not dissolve. A polar solvent is used for the solvent of the QD colloidal solution, the solvent of the ETL material colloidal solution, and the rinse liquid.

A flowchart illustrating an example of a manufacturing method for the light-emitting element 1 used in the present modification is the same as that in FIG. 3.

According to the present modification, the light-emitting element 1 illustrated in FIG. 1 can be manufactured without dissolving the QD-containing layer 13′ and the electron-transporting nanoparticle-containing layer 14′ through the method illustrated in FIG. 3 with the ligand 25, the solvent of the QD colloidal solution, the solvent 22 of the ligand solution 23, and the solvent used as the rinse liquid changed as described above.

The ligand 25 used in the present modification is not particularly limited as long as it is a monofunctional ligand having a polar functional group, and examples thereof include compounds including, as a molecular skeleton, a coordinating functional group that can coordinate to the QDs 131 and a polar functional group. Such compounds include [2-(2-methoxyethoxy)ethoxy]acetic acid, ethyl thioglycolate, and 3,6,9,12-tetraoxatridecan-1-amine.

Also in the present modification, as the polar solvent and the non-polar solvent, the polar solvent and the non-polar solvent described above in the present embodiment are preferably used.

### Second Embodiment

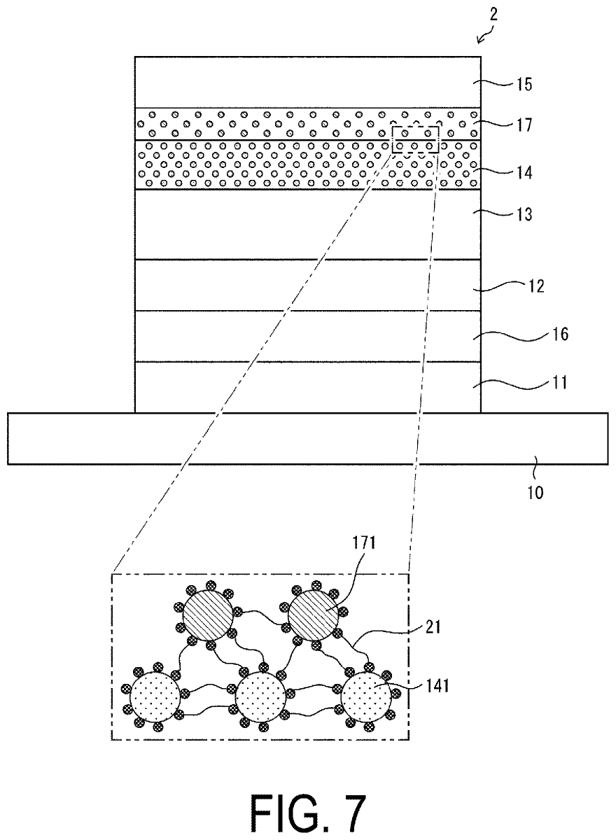

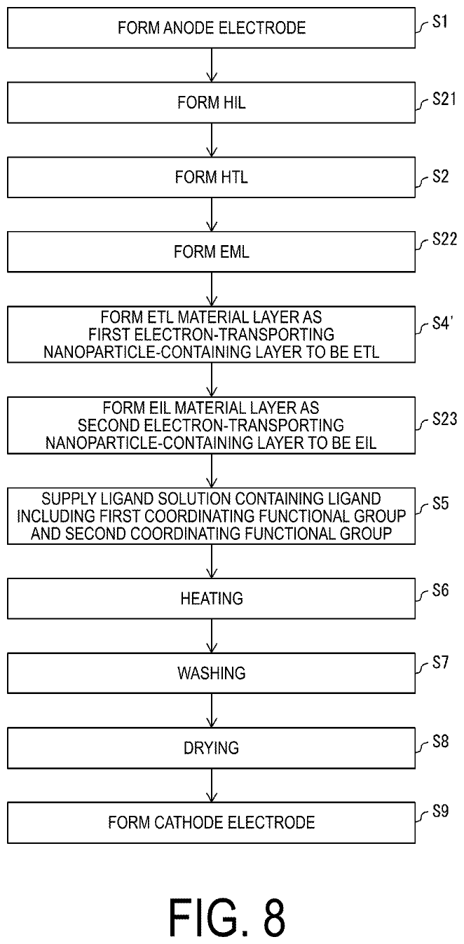

Another embodiment of the disclosure will be described as follows, with reference to FIGS. 7 and 8. Note that differences from the first embodiment will be described in the present embodiment. For convenience of description, members having the same functions as the members described in the first embodiment are designated by the same reference signs, and descriptions thereof are omitted.

### Overall Configuration of Light-Emitting Element

As described above, it suffices if the light-emitting element according to the disclosure has the ligand 21 including at least two coordinating functional groups at the interface between the first nanoparticle layer and the second nanoparticle layer disposed between the first electrode and the second electrode.

In the present embodiment, a case where the first nanoparticles are nanoparticles including the first carrier transport material and the second nanoparticles are nanoparticles including the second carrier transport material will be described as an example.

Hereinafter, as an example of the light-emitting element according to the present embodiment, a case where the first electrode (lower electrode) is the anode electrode, the second electrode (upper electrode) is the cathode electrode, the first nanoparticle layer (lower layer side nanoparticle-containing layer) is the ETL, and the second nanoparticle layer (upper layer side nanoparticle-containing layer) is the EIL will be described as an example.

FIG. 7 is a cross-sectional view illustrating an example of an overall configuration of a light-emitting element 2 according to the present embodiment in which a main portion of the light-emitting element is enlarged and schematically illustrated.

The light-emitting element 2 according to the present embodiment is the same as the light-emitting element 1 according to the first embodiment except for the following points.

The light-emitting element 2 illustrated in FIG. 7 includes the anode electrode 11, an HIL 16, the HTL 12, the EML 13, the ETL 14, an EIL 17, and the cathode electrode 15.

In the example illustrated in FIG. 7, the anode electrode 11, the HIL 16, the HTL 12, the EML 13, the ETL 14, the EIL 17, and the cathode electrode 15 are layered on a substrate 10 in this order from the substrate 10 side so as to be adjacent to each other.

Thus, the light-emitting element 2 may include the substrate 10 serving as the support body for forming each layer from the anode electrode 11 to the cathode electrode 15, as in the case of the light-emitting element 1.

The HIL 16 has positive hole-transporting properties and has a function of enhancing positive hole injection efficiency into the EML 13. The HIL 16 injects positive holes from the anode electrode 11 into the HTL 12. The material of the HIL 16 is not particularly limited as long as it is a positive hole transport material, and a known positive hole transport material can be used. As the material of the HIL 16, for example, the positive hole transport material described as an example in the first embodiment can be used.

Note that the HIL 16 is preferably formed using a material whose conduction band level or highest occupied molecular orbital (HOMO) level is deeper (lower) than the conduction band level or HOMO level of the HTL 12. This makes it easier for positive holes to enter into the HTL 12 than into the HIL 16, so that positive holes can be efficiently injected from the HIL 16 into the HTL 12, allowing the EML 13 to efficiently emit light.

Note that the HIL 16 is preferably formed using a material whose valence band level or lowest unoccupied molecular orbital (LUMO) level is deeper (lower) than the valence band level or LUMO level of the HTL 12. With this, electrons are unlikely to leak from the HTL 12 to the HIL 16, allowing the EML 13 to efficiently emit light.

The HIL 16 is preferably formed using a material in which the gap between the conduction band level and the valence band level or the gap between the HOMO level and the LUMO level is smaller than the gap between the conduction band level and the valence band level or the gap between the HOMO level and the LUMO level of the HTL 12. This makes it possible to provide the light-emitting element 1, in which positive holes easily move from the HIL 16 to the HTL 12, low voltage driving can be performed, and the luminous efficiency is high.

The EIL 17 has electron-transporting properties and has a function of enhancing electron injection efficiency into the EML 13. The EIL 17 injects electrons from the cathode electrode 15 into the ETL 14. In the present embodiment, the ETL 14 is the first nanoparticle layer and the EIL 17 is the second nanoparticle layer. The ETL 14 includes, for example, the nanoparticles 141 made of an electron transport material (first carrier transport material) as the first nanoparticles. The EIL 17 includes, for example, nanoparticles 171 made of an electron transport material (second carrier transport material) as the second nanoparticles. Thus, it suffices if the first nanoparticles and the second nanoparticles each include the electron transport material. Still, in the example illustrated in FIG. 7, both the first nanoparticle and the second nanoparticle are the electron transport material.

The nanoparticles 171 include nano-sized fine particles (inorganic nanoparticles) made of an inorganic compound and having electron-transporting properties. As the electron transport material used for the inorganic nanoparticle having electron-transporting properties, any of the electron transport materials given as examples of the nanoparticles 141 can be used. Similarly, only one type of these electron transport materials may be used, or two or more types thereof may be appropriately mixed and used.

As described in the first embodiment, the electron transport material is excellent in durability and in reliability, and the film formation can be carried out by an application method and is easy to be carried out. Among them, the electron transport materials is desirably metal oxide nanoparticles (in other words, fine particles of metal oxide or mixed crystal-based fine particles of the metal oxide), and is particularly desirably a semiconductor material containing zinc Zn atoms. The semiconductor material containing Zn atoms has high strength and can provide the light-emitting element 2 having particularly high mechanical strength.

Note that the EIL 17 is preferably formed using a material whose valence band level or LUMO level is shallower (higher) than the valence band level or LUMO level of the ETL 14. This makes it easier for electrons to enter into the ETL 14 than into the EIL 17, so that electrons can be efficiently injected from the EIL 17 into the ETL 14, allowing the EML 13 to efficiently emit light.

Note that the EIL 17 is preferably formed using a material whose conduction band level or HOMO level is shallower (higher) than the conduction band level or HOMO level of the ETL 14. With this, positive holes are unlikely to leak from the ETL 14 to the EIL 17, allowing the EML 13 to efficiently emit light.

The EIL 17 is preferably formed using a material in which the gap between the conduction band level and the valence band level or the gap between the HOMO level and the LUMO level is smaller than the gap between the conduction band level and the valence band level or the gap between the HOMO level and the LUMO level of the ETL 14. This makes it possible to provide the light-emitting element 1, in which electrons easily move from the EIL 17 to the ETL 14, low voltage driving can be performed, and the luminous efficiency is high.

Both the HOMO level and the LUMO level may be determined by an ordinary technique.

The number mean particle size (diameters) of the nanoparticles 171 is, for example, in a range of from 1 to 15 nm, and the number of overlapping layers of the nanoparticles 171 in the EIL 17 is, for example, from 1 to 10 layers.

The layer thickness of the HIL 16 and the layer thickness of the EIL 17 which may be known layer thicknesses, are for example, in a range of from 1 to 150 nm.

Still, also in the present embodiment, in order to facilitate the permeation of the ligand solution to the interface between the first nanoparticle layer and the second nanoparticle layer, the upper layer side nanoparticle-containing layer (second nanoparticle layer) is preferably thinner than the lower layer side nanoparticle-containing layer (first nanoparticle layer). Therefore, as illustrated in FIG. 7, the EIL 17 is preferably thinner than the ETL 14.

Also in the present embodiment, the density of the second nanoparticles in the second nanoparticle layer is desirably lower than the density of the first nanoparticles in the first nanoparticle layer in order to facilitate permeation of the ligand solution to the interface between the first nanoparticle layer and the second nanoparticle layer. Therefore, as illustrated in FIG. 7, it is desirable that the density of the nanoparticles 171 in the EIL 17 be lower than the density of the nanoparticles 141 in the ETL 14. Thus, the gaps between the nanoparticles 171 in the EIL 17 can be made larger than the gaps between the nanoparticles 141 in the ETL 14.

The light-emitting element 2 illustrated in FIG. 7 is an electroluminescent element that emits light when a voltage is applied to the EML 13, as in the case of the light-emitting element 1. Note that the light-emitting element 2 may also be used as, for example, a light source of a light-emitting device such as a display device or an illumination device, as in the case of the light-emitting element 1. However, the light-emitting element 2 may be a QLED, an inorganic electroluminescence (EL) element, or an organic light emitting diode (OLED, also referred to as an organic EL element).

When the light-emitting element 2 is an OLED or an inorganic EL element, the EML 13 is made of an organic light-emitting material or an inorganic light-emitting material such as a low molecular weight fluorescent (phosphorescent) dye or a metal complex for example.

In the case where the light-emitting element 2 is an OLED or an inorganic EL element, the conduction band level and the valence band level are replaced with the HOMO level and the LUMO level, respectively.

In the light-emitting element 2 according to the present embodiment, at least the nanoparticles 141 and the nanoparticles 171 adjacent to each other at the interface between the ETL 14 and the EIL 17 are bonded to each other by the same ligand including at least two coordinating functional groups (adsorption groups).

When the light-emitting element 2 is a QLED, in the light-emitting element 2, the nanoparticles 141 and the nanoparticles 171 adjacent to each other at the interface between the ETL 14 and the EIL 17 may be bonded to each other by the same ligand including at least two coordinating functional groups (adsorption groups), and the QDs 131 and the nanoparticles 141 adjacent to each other at the interface between the EML 13 and the ETL 14 may be bonded to each other by the same ligand including at least two coordinating functional groups (adsorption groups). In this case, the ligand that bonds the nanoparticles 141 and the nanoparticles 171 and the ligand that bonds the QDs 131 and the nanoparticles 141 may be the same or different, but are preferably the same.

As described above, the electron transport materials given as examples of the nanoparticles 141 can be used for the nanoparticles 171. Therefore, a ligand having a coordinating functional group exemplified in the first embodiment can be used as the above-described ligand. Thus, as illustrated in FIG. 7, the ligand 21 exemplified in the first embodiment can be used as the above-described ligand. In the following description, for convenience of description, bonding between the nanoparticles 141 and the nanoparticles 171 at the interface between the ETL 14 and the EIL 17 will be described as an example. The bonding between the QDs 131 and the nanoparticles 141 at the interface between the EML 13 and the ETL 14 when the ligand 21 is used as the above-described ligand is as described in the first embodiment.

The ligand 21 according to the present embodiment at least includes a coordinating functional group for coordinating (adsorbing) to the nanoparticles 141 as the first coordinating functional group, and includes a coordinating functional group for coordinating (adsorbing) to the nanoparticles 171 as the second coordinating functional group.

The ligand described above coordinates to the surfaces of the nanoparticles 141 and the nanoparticles 171, with the nanoparticles 141 and the nanoparticles 171 being receptors, and thus serves as a surface-modifying agent to modify the surfaces of the nanoparticles 141 and the nanoparticles 171. Also in the present embodiment, the first coordinating functional group and the second coordinating functional group may be the same type of coordinating functional group or may be different types of coordinating functional groups. Thus, the ligand 21 may include at least two coordinating functional groups of at least one type as described in the first embodiment.

According to the present embodiment, as illustrated in FIG. 7, since the light-emitting element 2 has the ligand 21 at the interface between the ETL 14 and the EIL 17, the nanoparticles 141 and the nanoparticles 171 can be immobilized via the ligand 21 at the interface between the ETL 14 and the EIL 17. Therefore, according to the present embodiment, it is possible to prevent or suppress at the interface between the ETL 14 and the EIL 17, mixing of the nanoparticles 141 and the nanoparticles 171 and formation of a mixed layer of the nanoparticles 141 and the nanoparticles 171 when a voltage for driving the light-emitting element 2 is applied to the light-emitting element 2. Therefore, according to the present embodiment, electromigration at the interface between the ETL 14 and the EIL 17 can be suppressed or prevented, and the influence of electromigration at the interface between the ETL 14 and the EIL 17 can be suppressed or eliminated. Further, according to the present embodiment, since the nanoparticles 141 and the nanoparticles 171 can be immobilized via the ligand 21 at the interface between the ETL 14 and the EIL 17, layer peeling between the ETL 14 and the EIL 17 at the interface between the ETL 14 and the EIL 17 can be suppressed.

According to the present embodiment, since the nanoparticles 141 and the nanoparticles 171 are bonded to each other by the ligand 21 at the interface between the ETL 14 and the EIL 17, electrons are injected from the nanoparticles 171 to the nanoparticles 141 via the ligand 21 common to the nanoparticles 141 and the nanoparticles 171. Therefore, the loss of electrons at the time of electron injection in the light-emitting element 2 can be reduced.

### Manufacturing Method for Light-Emitting Element 2

Next, an example of a manufacturing method for the light-emitting element 2 according to the present embodiment will be described.

FIG. 8 is a flowchart illustrating an example of an overview of the manufacturing method for the light-emitting element 2 according to the present embodiment.

As illustrated in FIG. 8, in a manufacturing process for the light-emitting element 2 according to the present embodiment, first, as an example, for example, the anode electrode 11 is formed on the substrate 10 (step S1: anode electrode forming process). Subsequently, the HIL 16 is formed (step S21: HIL forming process). Subsequently, the HTL 12 is formed (step S2: HTL forming process). Subsequently, the EML 13 is formed (step S22: EML forming process). Then, a solid ETL material layer is formed as a first electron-transporting nanoparticle-containing layer to be the ETL 14 (step S4′: first electron-transporting nanoparticle-containing layer forming process, ETL material layer forming process, first nanoparticle containing layer forming process). Then, a solid EIL material layer is formed as a second electron-transporting nanoparticle-containing layer to be the EIL 17 (step S23: second electron-transporting nanoparticle-containing layer forming process, EIL material layer forming process, second nanoparticle containing layer forming process). Next, a ligand solution containing the ligand 21 including the first coordinating functional group and the second coordinating functional group is supplied onto the EIL material layer (step S5: ligand solution supplying process). Next, the layered body after the ligand solution is supplied (substrate 10 to EIL material layer in the present embodiment) is heated (step S6: heating process), washed (step S7: washing process), and dried (step S8: drying process). As a result, the EIL 17 made of the EIL material layer is formed. Furthermore, the ETL 14 made of the ETL material layer is formed. Subsequently, the cathode electrode 15 is formed (step S9: cathode electrode forming process).

For the formation of the HIL 16 in step S21, various known methods for forming the HIL can be used. The HIL 16 can be formed using the same or a similar method as that for the HTL 12.

For the formation of the EML13 in step S22, various known methods for forming the EML can be used. When the light-emitting element 2 is a QLED, the EML 13 can be formed by, for example, applying and drying a QD colloidal solution (QD dispersion liquid) containing the QDs 131. When the light-emitting element 2 is an OLED or an inorganic EL device, the EML 13 can be formed, for example, by applying the above-described organic light-emitting material or inorganic light-emitting material by a vapor deposition method, an ink-jet method, or the like and drying the applied material.

For the formation of the EIL material layer (second electron-transporting nanoparticle-containing layer) in step S23, the same or a similar method as the method of forming the ETL material layer (first electron-transporting nanoparticle-containing layer) can be used. The EIL material layer can be formed in the same manner as in step S4′, except that the nanoparticles 171 are used instead of the nanoparticles 141 in step S4′.

The processes other than the above-described step S21 and step S22 (step S1, step S2 to step S4′, step S5 to step S9) are the same as those described in the first embodiment except that the underlying layer is different, the non-polar solvent is used as the solvent of the ligand solution, and the polar solvent is used as the solvent of the rinse liquid.

Also in the present embodiment, the supply amount of the ligand solution in the ligand exchange process (step S5) is not particularly limited as long as the amount is set to an amount with which the ligand 21 in the ligand solution can at least reach the interface between the nanoparticle layers layered adjacent to each other and bond the nanoparticles of the respective layers at the interface, as in the first embodiment. In order to uniformly apply the ligand solution onto the upper layer side nanoparticle-containing layer (the EIL material layer in the present embodiment), the ligand solution may be supplied (for example, dispersed) onto the upper layer side nanoparticle-containing layer, and then the supplied ligand solution may be applied on the surface of the upper layer side nanoparticle-containing layer by spin coating.

Also in the present embodiment, when the ligand solution is supplied onto the upper layer side nanoparticle-containing layer, the ligand solution permeates from the upper layer side nanoparticle-containing layer toward the lower layer side nanoparticle-containing layer (in the present embodiment, the ETL material layer). At this time, when the upper layer side nanoparticle-containing layer and the lower layer side nanoparticle-containing layer do not contain the ligand 25, the ligand 21 coordinates to each of the first nanoparticles (the nanoparticles 141 in the present embodiment) and the second nanoparticles (the nanoparticles 171 in the present embodiment). On the other hand, when at least one of the upper layer side nanoparticle-containing layer and the lower layer side nanoparticle-containing layer contains the ligand 25, at least part of the ligand 25 is exchanged with the ligand 21.

Also in the present embodiment, a portion of the lower layer side nanoparticle-containing layer closer to the interface with the upper layer side nanoparticle-containing layer is thus substituted by the ligand 21 (or coordinated with the ligand 21) at a higher concentration. The rate of exchange by the ligand 21 (the rate of being coordinated with the ligand 21) is lower at a portion farther from the interface. Also in the present embodiment, for example, when at least one of the lower layer side nanoparticle-containing layer and the upper layer side nanoparticle-containing layer contains the ligands 25, the ligand 25 can be entirely exchanged with the ligand 21 by adjusting the supply amount, viscosity, concentration, and the like of the ligand solution 23.

In any case, in the present embodiment, it suffices if the nanoparticles 141 and the nanoparticles 171 are finally immobilized (bonded) via the ligand 21 at the interface between the ETL 14 and the EIL 17. This makes it possible to suppress or prevent electromigration at the interface. Therefore, the ligands 21 may coordinate to the nanoparticles 141 and the nanoparticles 171 over the entire layering direction, but this is not necessarily required.

When the EML 13 might be dissolved in a non-polar solvent, the supply amount, viscosity, concentration, and the like of the ligand solution may be adjusted so that the ligand solutions do not permeate to the EML 13.

On the other hand, when step S3 and steps S11 to S14 described in the first modification of the first embodiment are performed instead of step S22, or when a monofunctional ligand having a polar bonding group is used as the ligand 25 as described in the second modification of the first embodiment, the EML 13 would not be dissolved in a non-polar solvent. When the EML 13 contains the QDs 131 and the EML 13 would not be dissolved in a non-polar solvent, the ligand solution can be further permeated from the first electron-transporting nanoparticle-containing layer toward the layer containing the QDs 131 by adjusting the supply amount, viscosity, concentration and the like of the ligand solution.

In this case, as described above, the nanoparticles 141 and the nanoparticles 171 adjacent to each other at the interface between the ETL 14 and the EIL 17 can be bonded by the ligand 21, and the QDs 131 and the nanoparticles 141 adjacent to each other at the interface between the EML 13 and the ETL 14 can be bonded by the ligand 21. Thus, the effect of the present embodiment described above and the effect described in the first embodiment can be obtained in combination.

### Third Embodiment

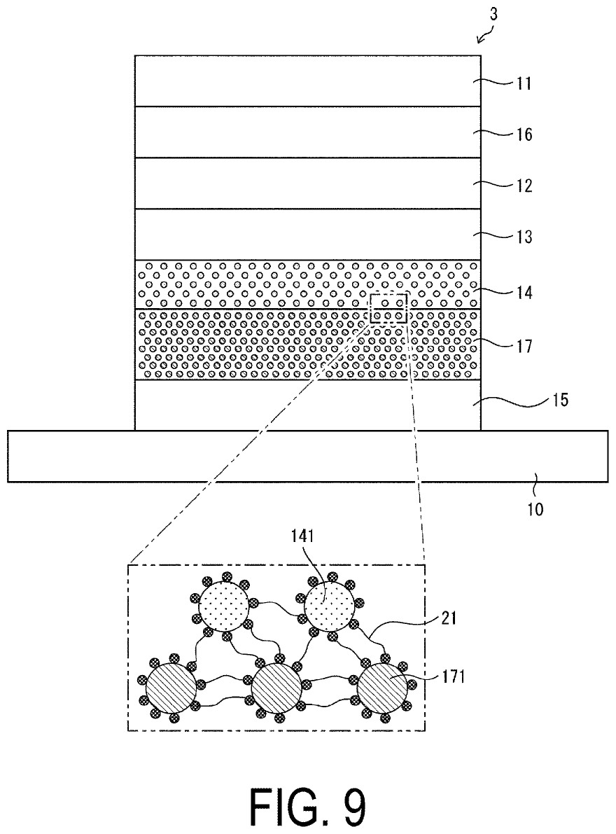

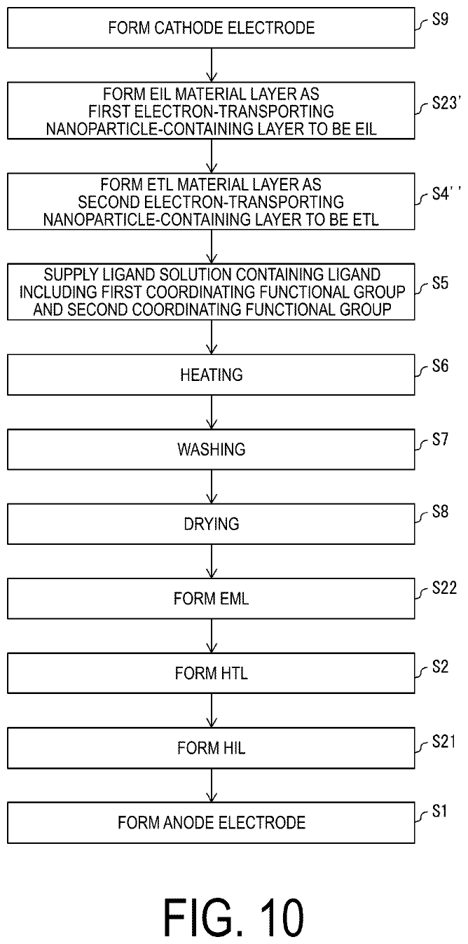

Still another embodiment of the disclosure will be described as follows, with reference to FIGS. 9 and 10. Note that differences from the first and the second embodiments will be described in the present embodiment. For convenience of description, members having the same functions as the members described in the first and second embodiments are designated by the same reference signs, and descriptions thereof are omitted.

### Overall Configuration of Light-Emitting Element

FIG. 9 is a cross-sectional view illustrating an example of an overall configuration of a light-emitting element 3 according to the present embodiment in which a main portion of the light-emitting element is enlarged and schematically illustrated.

The light-emitting element 3 according to the present embodiment is the same as the light-emitting element 2 according to the second embodiment except for the following points.

In the example described in the second embodiment, the light-emitting element 2 has the conventional structure in which the anode electrode 11 is formed on the substrate 10 and the cathode electrode 15 is formed on the side opposite to the substrate 10 with the EML 13 interposed therebetween. However, the light-emitting element according to the disclosure is not limited thereto.

The light-emitting element 3 according to the present embodiment is a light-emitting element having an inverted structure in which the cathode electrode 15 is formed on the substrate 10 and the anode electrode 11 is formed on the side opposite to the substrate 10 with the EML 13 interposed therebetween. In the light-emitting element having the inverted structure, since the EML 13 is layered on the ETL 14, deterioration of the EML 13 due to formation of the ETL 14 can be suppressed.

In the light-emitting element 3 illustrated in FIG. 9, the cathode electrode 15, the EIL 17, the ETL 14, the EML 13, the HTL 12, the HIL 16, and the anode electrode 11 are layered adjacent to each other on the substrate 10 in this order from the side of the substrate 10.

In the present embodiment, the first electrode is the cathode electrode, the second electrode is the anode electrode, the EIL 17 is the first nanoparticle layer, and the ETL 14 is the second nanoparticle layer. Therefore, in the present embodiment, the first nanoparticles are the nanoparticles 171 made of an electron transport material (first carrier transport material), and the second nanoparticles are the nanoparticles 141 made of an electron transport material (second carrier transport material).

Therefore, in the present embodiment, in order to facilitate the permeation of the ligand solution 23 to the interface between the EIL 17 and the ETL 14, the ETL 14 is preferably thinner than the EIL 17 as illustrated in FIG. 9. In addition, in the present embodiment, as illustrated in FIG. 9, it is desirable that the density of the nanoparticles 141 in the ETL 14 be lower than the density of the nanoparticles 171 in the EIL 17 so that the ligand solution 23 can be easily permeated to the interface between the EIL 17 and the ETL 14. Thus, the gaps between the nanoparticles 141 in the ETL 14 can be made larger than the gaps between the nanoparticles 171 in the EIL 17.

The light-emitting element 3 illustrated in FIG. 9 is an electroluminescent element that emits light when a voltage is applied to the EML 13, as in the case of the light-emitting element 2. Note that the light-emitting element 3 may also be used as, for example, a light source of a light-emitting device such as a display device or an illumination device, as in the case of the light-emitting elements 1 and 2. Like the light-emitting element 2, the light-emitting element 3 may be a QLED, an inorganic EL element, or an OLED.

In the light-emitting element 3 according to the present embodiment, at least the nanoparticles 171 and the nanoparticles 141 adjacent to each other at the interface between the EIL 17 and the ETL 14 may be bonded to each other by the same ligand 21 including at least two coordinating functional groups (adsorption groups).

Thus, in the following description, for convenience of description, bonding between the nanoparticles 171 and the nanoparticles 141 at the interface between the EIL 17 and the ETL 14 will be described as an example.

The ligand 21 according to the present embodiment at least includes a coordinating functional group for coordinating (adsorbing) to the nanoparticles 171 as the first coordinating functional group, and includes a coordinating functional group for coordinating (adsorbing) to the nanoparticles 141 as the second coordinating functional group. Also in the present embodiment, the first coordinating functional group and the second coordinating functional group may be the same type of coordinating functional group or may be different types of coordinating functional groups. Thus, the ligand 21 may include at least two coordinating functional groups of at least one type as described in the first embodiment and the second embodiment.

According to the present embodiment, as illustrated in FIG. 9, since the light-emitting element 3 has the ligand 21 at the interface between the EIL 17 and the ETL 14, the nanoparticles 171 and the nanoparticles 141 can be immobilized via the ligand 21 at the interface between the EIL 17 and the ETL 14. Therefore, also according to the present embodiment, as in the light-emitting element 2, it is possible to prevent or suppress at the interface between the EIL 17 and the ETL 14, mixing of the nanoparticles 171 and the nanoparticles 141 and formation of a mixed layer of the nanoparticles 171 and the nanoparticles 141 when a voltage for driving the light-emitting element 3 is applied to the light-emitting element 3. Therefore, according to the present embodiment, electromigration at the interface between the EIL 17 and the ETL 14 can be suppressed or prevented, and the influence of electromigration at the interface between the EIL 17 and the ETL 14 can be suppressed or eliminated. Further, also according to the present embodiment, since the nanoparticles 171 and the nanoparticles 141 can be immobilized via the ligand 21 at the interface between the EIL 17 and the ETL 14, layer peeling between the EIL 17 and the ETL 14 at the interface between the EIL 17 and the ETL 14 can be suppressed.

Also according to the present embodiment, since the nanoparticles 171 and the nanoparticles 141 are bonded to each other by the ligand 21 at the interface between the EIL 17 and the ETL 14, electrons are injected from the nanoparticles 171 to the nanoparticles 141 via the ligand 21 common to the nanoparticles 171 and the nanoparticles 141. Therefore, the loss of electrons at the time of electron injection in the light-emitting element 2 can be reduced.

### Manufacturing Method for Light-Emitting Element 3

Next, an example of a manufacturing method for the light-emitting element 3 according to the present embodiment will be described.

FIG. 10 is a flowchart illustrating an example of an overview of the manufacturing method for the light-emitting element 3 according to the present embodiment.

As illustrated in FIG. 10, in a manufacturing process for the light-emitting element 3 according to the present embodiment, first, as an example, for example, the cathode electrode 15 is formed on the substrate 10 (step S9: cathode electrode forming process). Then, a solid EIL material layer is formed as a first electron-transporting nanoparticle-containing layer to be the EIL 17 (step S23′: first electron-transporting nanoparticle-containing layer forming process, EIL material layer forming process, first nanoparticle containing layer forming process). Then, a solid ETL material layer is formed as a second electron-transporting nanoparticle-containing layer to be the ETL 14 (step S4″: second electron-transporting nanoparticle-containing layer forming process, ETL material layer forming process, second nanoparticle containing layer forming process). Next, a ligand solution containing the ligand 21 including the first coordinating functional group and the second coordinating functional group is supplied onto the ETL material layer (step S5: ligand solution supplying process). Next, the layered body after the ligand solution is supplied (substrate 10 to ETL material layer in the present embodiment) is heated (step S6: heating process), washed (step S7: washing process), and dried (step S8: drying process). As a result, the ETL 14 made of the ETL material layer is formed. Furthermore, the EIL 17 made of the ETL material layer is formed. Subsequently, the EML 13 is formed (step S22: EML forming process). Subsequently, the HTL 12 is formed (step S2: HTL forming process). Subsequently, the HIL 16 is formed (step S21: HIL forming process). Subsequently, the anode electrode 11 is formed (step S1: anode electrode forming process).

The above-described processes are the same as those described in the second embodiment except that the underlying layer is different due to the different formation order as described above.

Also in the present embodiment, in order to uniformly apply the ligand solution onto the upper layer side nanoparticle-containing layer (the ETL material layer in the present embodiment), the ligand solution may be supplied (for example, dispersed) onto the upper layer side nanoparticle-containing layer, and then the supplied ligand solution may be applied on the surface of the upper layer side nanoparticle-containing layer by spin coating.

Also in the present embodiment, when the ligand solution is supplied onto the upper layer side nanoparticle-containing layer, the ligand solution permeates from the upper layer side nanoparticle-containing layer toward the lower layer side nanoparticle-containing layer (in the present embodiment, the EIL material layer). At this time, when the upper layer side nanoparticle-containing layer and the lower layer side nanoparticle-containing layer do not contain the ligand 25, the ligand 21 coordinates to each of the first nanoparticles (the nanoparticles 141 in the present embodiment) and the second nanoparticles (the nanoparticles 171 in the present embodiment). On the other hand, when at least one of the upper layer side nanoparticle-containing layer and the lower layer side nanoparticle-containing layer contains the ligand 25, at least part of the ligand 25 is exchanged with the ligand 21.

Also in the present embodiment, a portion of the lower layer side nanoparticle-containing layer closer to the interface with the upper layer side nanoparticle-containing layer is thus substituted by the ligand 21 (or coordinated with the ligand 21) at a higher concentration. The rate of exchange by the ligand 21 (the rate of being coordinated with the ligand 21) is lower at a portion farther from the interface. Also in the present embodiment, for example, when at least one of the lower layer side nanoparticle-containing layer and the upper layer side nanoparticle-containing layer contains the ligands 25, the ligand 25 can be entirely exchanged with the ligand 21 by adjusting the supply amount, viscosity, concentration, and the like of the ligand solution 23.

In any case, also in the present embodiment, it suffices if the nanoparticles 141 and the nanoparticles 171 are finally immobilized (bonded) via the ligand 21 at the interface between the ETL 14 and the EIL 17. This makes it possible to suppress or prevent electromigration at the interface. Therefore, the ligands 21 may coordinate to the nanoparticles 141 and the nanoparticles 171 over the entire layering direction, but this is not necessarily required.

### First Modified Example

In the description above, bonding between the nanoparticles 171 and the nanoparticles 141 at the interface between the EIL 17 and the ETL 14 is described as an example. However, as described above, when the light-emitting element 3 is a QLED, the EML 13 includes the QDs 131, and the ligand 25 is a monofunctional ligand having a polar bonding group, the cathode electrode forming process (step S9), the first electron-transporting nanoparticle-containing layer forming process (step S23′: EIL material layer forming process), the second electron-transporting nanoparticle-containing layer forming process (step S4″: ETL material layer forming process), the QD-containing layer forming process (step S3), the ligand solution supplying process (step S5), the heating process (step S6), the washing process (step S7), the drying process (step S8), the HTL forming process (step S2), the HIL forming process (step S21), and the anode electrode forming process (step S1) may be performed in this order for example.

When the light-emitting element 3 is a QLED, the EML 13 includes the QDs 131, and the ligand 25 alone and the QDs 131 and the ligand 25 in the state where the ligand 25 has coordinated to the QDs 131 are dissolved in a non-polar solvent, for example, the cathode electrode forming process (step S9), the first electron-transporting nanoparticle-containing layer forming process (step S23′: the EIL material layer forming process), the second electron-transporting nanoparticle-containing layer forming process (step S4″: the ETL material layer forming process), the first ligand solution supplying process (step S11), the heating process (step S12), the washing process (step S13), the drying process (step S14), the QD-containing layer forming process (step S3), the second ligand solution supplying process (step S5′), the heating process (step S6), the washing process (step S7), the drying process (step S8), the HTL forming process (step S2), the HIL forming process (step S21), and the anode electrode forming process (step S1) may be performed in this order. The first ligand solution supplying process (step S11) is the same as, for example, step S11 illustrated in FIG. 6 in the first embodiment and step S5 illustrated in FIG. 10 in the present embodiment, except that the first ligand solution containing the ligand 21 including the first coordinating functional group and the second coordinating functional group is supplied onto the ETL material layer. The second ligand solution supplying process (step S5′) is the same as, for example, step S5′ illustrated in FIG. 6 in the first embodiment and step S5 illustrated in FIG. 10 in the present embodiment except that the second ligand solution containing the ligand 21 including the first coordinating functional group and the second coordinating functional group is supplied onto the QD-containing layer 13′.

Thus, when the EML 13 includes the QDs 131, the QDs 131 and the nanoparticles 141 adjacent to each other at the interface between the EML 13 and the ETL 14 can be bonded by the ligand 21, and the nanoparticles 141 and the nanoparticles 171 adjacent to each other at the interface between the ETL 14 and the EIL 17 can be bonded by the ligand 21. Thus, the effect of the present embodiment described above and the effect described in the first embodiment can be obtained in combination.

### Second Modified Example

In the present embodiment, the case where the first nanoparticles and the second nanoparticles are made of an electron transport material (strictly, nanoparticles made of an electron transport material) is described as an example, but the present embodiment is not limited thereto. The first nanoparticle layer and the second nanoparticle layer according to the present embodiment may be carrier transport layers adjacent to each other, and the first nanoparticles and the second nanoparticles may be a positive hole transport material (strictly, nanoparticles made of a positive hole transport material).

Therefore, when the light-emitting element according to the disclosure has an inverted structure as described above, the first nanoparticle layer may be the HTL 12 and the second nanoparticle layer may be the HIL 16. In this case, the HTL 12 may contain nanoparticles made of a positive hole transport material (first carrier transport material) as the first nanoparticles. The HIL 16 may contain nanoparticles made of a positive hole transport material (second carrier transport material) as the second nanoparticles.

The light-emitting element according to the disclosure may have a conventional structure as described in the second embodiment. Thus, the first nanoparticle layer may be the HIL 16 and the second nanoparticle layer may be the HTL 12. When the light-emitting element thus has the conventional structure, the HIL 16 may contain nanoparticles made of a positive hole transport material (first carrier transport material) as the first nanoparticles. The HTL 12 may contain nanoparticles made of a positive hole transport material (second carrier transport material) as the second nanoparticles.

The first nanoparticles and the second nanoparticles include nano-sized fine particles (inorganic nanoparticles) made of an inorganic compound and having positive hole-transporting properties. The positive hole transport material used for the inorganic nanoparticles having positive hole-transporting properties include an inorganic compound such as an p-type semiconductor. Examples of the p-type semiconductor include metal oxide, a group II-VI compound semiconductor, a group III-V compound semiconductor, a group IV-IV compound semiconductor, an amorphous semiconductor, and a thiocyanic acid compound. Examples of the metal oxide include zinc oxide (ZnO), titanium oxide (TiO₂), indium oxide (In₂O₃), tin oxide (SnO, SnO₂), and cerium oxide (CeO₂). Examples of the group II-VI compound semiconductor include zinc sulfide (ZnS) and zinc selenide (ZnSe). Examples of the group III-V compound semiconductor include aluminum arsenide (AlAs), gallium arsenide (GaAs), indium arsenide (InAs), aluminum nitride (AlN), gallium nitride (GaN), indium nitride (InN), and gallium phosphide (GaP). Examples of the group IV-IV compound semiconductor include silicon germanium (SiGe) and silicon carbide (SiC). Examples of the amorphous semiconductor include p-type hydrogenated amorphous silicon and p-type hydrogenated amorphous silicon carbide. Examples of the thiocyanic acid compound include thiocyanates such as copper thiocyanate. Only one type of these positive hole transport materials may be used, or two or more types thereof may be appropriately mixed and used.

These positive hole transport materials are excellent in durability and in reliability, and the film formation can be carried out by an application method and is easy to be carried out. Among them, the positive hole transport materials is desirably metal oxide nanoparticles (in other words, fine particles of metal oxide or mixed crystal-based fine particles of the metal oxide), and is particularly desirably a semiconductor material containing zinc (Zn) atoms. The semiconductor material containing Zn atoms has high strength and can provide the light-emitting element 3 having particularly high mechanical strength.

When the first nanoparticles and the second nanoparticles are inorganic nanoparticles having positive hole-transporting properties as described above, the number mean particle sizes (diameters) of the first nanoparticles and the second nanoparticles are, for example, in a range of from 1 to 15 nm. The number of overlapping layers of the first nanoparticles and the number of overlapping layers of the second nanoparticles in the HIL 16 and the HTL 12 are each, for example, from 1 to 10 layers. The layer thickness of the HIL 16 and the layer thickness of the HTL 12 which may be known layer thicknesses, are for example, in a range of from 1 to 150 nm.

Still, in any case, in order to facilitate the permeation of the ligand solution to the interface between the first nanoparticle layer and the second nanoparticle layer, the upper layer side nanoparticle layer (second nanoparticle layer) is preferably thinner than the lower layer side nanoparticle layer (first nanoparticle layer). The density of the second nanoparticles in the second nanoparticle layer is desirably lower than the density of the first nanoparticles in the first nanoparticle layer in order to facilitate permeation of the ligand solution to the interface between the first nanoparticle layer and the second nanoparticle layer.

Also in the present modification, the ligand having the coordinating functional group exemplified in the first embodiment can be used as the ligand for bonding the first nanoparticles and the second nanoparticles at the interface between the first nanoparticle layer and the second nanoparticle layer. Thus, the ligand 21 exemplified in the first embodiment can be used as the above-described ligand.

According to the present modification, since the light-emitting element has the ligand 21 at the interface between the HTL 12 and the HIL 16, the nanoparticles included in the respective layers can be immobilized to each other via the ligand 21 at the interface between the HTL 12 and the HIL 16. Therefore, according to the present modification, when a voltage for driving the light-emitting element is applied to the light-emitting element, mixing of the nanoparticles of the respective layers at the interface between the HTL 12 and the HIL 16 can be prevented or suppressed. Therefore, according to the present modification, electromigration at the interface between the HTL 12 and the HIL 16 can be suppressed or prevented, and the influence of electromigration at the interface between the HTL 12 and the HIL 16 can be suppressed or eliminated. In addition, according to the present modification, since the nanoparticles of the respective layers can be immobilized to each other via the ligand 21 at the interface between the HTL 12 and the HIL 16, layer peeling between the HTL 12 and the HIL 16 at the interface between the HTL 12 and the HIL 16 can be suppressed.

According to the present modification, since the nanoparticles of the respective layers are bonded to each other by the ligand 21 at the interface between the HTL 12 and the HIL 16, positive holes are injected from the nanoparticles of the HIL 16 to the nanoparticles of the HTL 12 via the ligand 21 common to the nanoparticles of the respective layers. Therefore, the loss of positive holes at the time of positive hole injection in the light-emitting element can be reduced.

Also in the present modification, the light-emitting element may be a QLED, an inorganic EL element, or an OLED. Therefore, the luminescent material in the EML 13 may be QDs, an organic light-emitting material, or an inorganic light-emitting material. When the light-emitting element is a QLED, the ligand 21 may also be provided at the interface between the EML 13 and the HTL 12.

Further, in the present modification, the EIL 17 may not be provided. The electron transport material used for the ETL 14 and the EIL 17 does not need to be nanoparticles, and may be, for example, an organic material. When the electron transport material is the organic electron transport material, examples of the organic electron transport material include 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), and tris(2,4,6-trimethyl-3-(pyridin-3-yl)phenyl)borane (3TPYMB).

### Third Modified Example

As can be understood from the above description, in the light-emitting element according to an embodiment of the disclosure, the first nanoparticles may be the QDs 131, and the second nanoparticles may be a positive hole transport material (strictly, a nanoparticle made of a positive hole transport material). In addition, the first nanoparticles may be a positive hole transport material (strictly, a nanoparticle formed of a positive hole transport material), and the second nanoparticles may be the QDs 131. The layered structure of the light-emitting element is not particularly limited as long as the light-emitting element has a structure in which one of the EML 13 and the HTL 12 is layered adjacent to the other for example.

According to the present modification, since the light-emitting element has the ligand 21 at the interface between the HTL 12 and the EML 13 for example, the nanoparticles included in the respective layers can be immobilized to each other via the ligand 21 at the interface between the HTL 12 and the EML 13. Therefore, according to the present modification, when a voltage for driving the light-emitting element is applied to the light-emitting element, mixing of the nanoparticles of the respective layers at the interface between the HTL 12 and the EML 13 can be prevented or suppressed. Therefore, according to the present modification, electromigration at the interface between the HTL 12 and the EML 13 can be suppressed or prevented, and the influence of electromigration at the interface between the HTL 12 and the EML 13 can be suppressed or eliminated. In addition, according to the present modification, since the nanoparticles of the respective layers can be immobilized to each other via the ligand 21 at the interface between the HTL 12 and the EML 13, layer peeling between the HTL 12 and the EML 13 at the interface between the HTL 12 and the EML 13 can be suppressed.

According to the present modification, since the nanoparticles of the respective layers are bonded to each other by the ligand 21 at the interface between the HTL 12 and the EML 13, positive holes are injected from the nanoparticles of the HTL 12 to the nanoparticles of the EML 13, that is, the QDs 131 via the ligand 21 common to the nanoparticles of the layers. Therefore, the loss of positive holes at the time of positive hole injection in the light-emitting element can be reduced.

### Fourth Embodiment

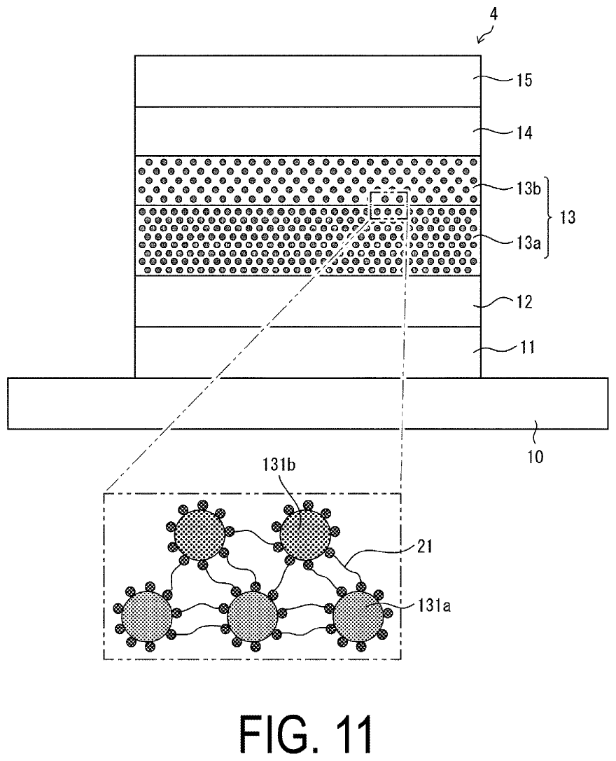

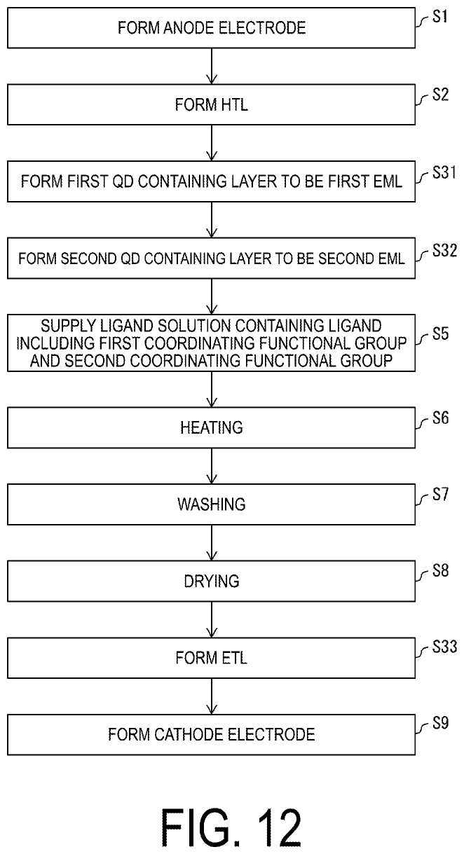

Still another embodiment of the disclosure will be described as follows, with reference to FIGS. 11 and 12. Note that differences from the first to third embodiments will be described in the present embodiment. For convenience of description, members having the same functions as the members described in the first to third embodiments are designated by the same reference signs, and descriptions thereof are omitted.

### Overall Configuration of Light-Emitting Element

FIG. 11 is a cross-sectional view illustrating an example of an overall configuration of a light-emitting element 4 according to the present embodiment in which a main portion of the light-emitting element is enlarged and schematically illustrated.

The light-emitting element 4 according to the present embodiment is the same as the light-emitting element according to the first to third embodiments except for the following points.

In the first to third embodiments, the case in which at least one of the first nanoparticle layer and the second nanoparticle layer is a carrier transport layer is exemplified and explained. However, the light-emitting element according to the disclosure is not limited thereto, and each of the first nanoparticle layer and the second nanoparticle layer may be the EML.

As an example, in the light-emitting element 4 illustrated in FIG. 11, the anode electrode 11, the HTL 12, the EML 13, the ETL 14, and the cathode electrode 15 are layered on the substrate 10 so as to be adjacent to each other in this order from the substrate 10 side.

Thus, the light-emitting element 4 may include the substrate 10 serving as the support body for forming each layer from the anode electrode 11 to the cathode electrode 15, as in the case of the light-emitting element 1. Although FIG. 11 illustrates an example in which the light-emitting element 4 has a conventional structure, the light-emitting element 4 may have an inverted structure or may include layers other than the above-described layers such as the HIL 16 and the EIL 17.

As illustrated in FIG. 11, the EML 13 according to the present embodiment includes an EML 13a including QDs 131a (first QDs) and an EML 13b including QDs 131b (second QDs).

In the present embodiment, the EML 13a is the first nanoparticle layer and the EML 13b is the second nanoparticle layer. Therefore, in the present embodiment, the first nanoparticles are the QDs 131a and the second nanoparticles are the QDs 131b.

Thus, also in the present embodiment, the ligand having the coordinating functional group exemplified in the first embodiment can be used as the ligand for bonding the first nanoparticles and the second nanoparticles at the interface between the first nanoparticle layer and the second nanoparticle layer. Thus, the ligand 21 exemplified in the first embodiment can be used as the above-described ligand.

According to the present embodiment, as illustrated in FIG. 11, since the light-emitting element 4 has the ligand 21 at the interface between the EML 13a and the EML 13b, the QDs 131a and the QDs 131b can be immobilized via the ligand 21 at the interface between the EML 13a and the EML 13b. Therefore, according to the present embodiment, it is possible to prevent or suppress at the interface between the EML 13a and the EML 13b, mixing of the QDs 131a and the QDs 131b and formation of a mixed layer of the QDs 131a and the QDs 131b when a voltage for driving the light-emitting element 4 is applied to the light-emitting element 4. Therefore, according to the present embodiment, electromigration at the interface between the EML 13a and the EML 13b can be suppressed or prevented, and the influence of electromigration at the interface between the EML 13a and the EML 13b can be suppressed or eliminated. Further, according to the present embodiment, since the QDs 131a and the QDs 131b can be immobilized via the ligand 21 at the interface between the EML 13a and the EML 13b, layer peeling between the EML 13a and the EML 13b at the interface between the EML 13a and the EML 13b can be suppressed.

Also in the present embodiment, in order to facilitate the permeation of the ligand solution 23 to the interface between the first nanoparticle layer and the second nanoparticle layer, the second nanoparticle layer is preferably thinner than the first nanoparticle layer. The density of the second nanoparticles in the second nanoparticle layer is desirably lower than the density of the first nanoparticles in the first nanoparticle layer in order to facilitate permeation of the ligand solution 23 to the interface between the first nanoparticle layer and the second nanoparticle layer.

Therefore, in the present embodiment, the EML 13b is preferably thinner than the EML 13a. Further, the density of the QDs 131b in the EML 13b is preferably lower than the density of the QDs 131a in the EML 13a.

### Manufacturing Method for Light-Emitting Element 4

Next, an example of a manufacturing method for the light-emitting element 4 according to the present embodiment will be described.

FIG. 12 is a flowchart illustrating an example of an overview of the manufacturing method for the light-emitting element 4 according to the present embodiment.

As illustrated in FIG. 12, in a manufacturing process for the light-emitting element 4 according to the present embodiment, first, as an example, for example, the anode electrode 11 is formed on the substrate 10 (step S1: anode electrode forming process). Subsequently, the HTL 12 is formed (step S2: HTL forming process). Next, for example, a layer including the QDs 131a and the ligand 25 is formed as a first QD containing layer including the QDs 131a to be the EML 13a (step S31: first EML forming process). Next, for example, a layer including the QDs 131b and the ligand 25 is formed as a second QD containing layer including the QDs 131b to be the EML 13b (step S32: second EML forming process). Next, the ligand solution 23 containing the ligand 21 including the first coordinating functional group and the second coordinating functional group is supplied onto the first QD containing layer (step S5: ligand solution supplying process). Next, the layered body after the ligand solution 23 is supplied (substrate 10 to second QD containing layer in the present embodiment) is heated (step S6: heating process), washed (step S7: washing process), and dried (step S8: drying process). Subsequently, the ETL 14 is formed (step S33: ETL forming process). Subsequently, the cathode electrode 15 is formed (step S9: cathode electrode forming process).

The first QD containing layer can be formed by, for example, applying and drying a QD colloidal solution (QD dispersion liquid) containing the QDs 131a in step S31. Step S31 is the same as step S3 except that the QDs 131a are used as the QDs.

Similarly, the second QD-containing layer can be formed by, for example, applying and drying a QD colloidal solution (QD dispersion liquid) containing the QDs 131b in step S32. Step S32 is the same as step S3 except that the QDs 131b are used as the QDs.

As described above, the EML 13a according to the present embodiment is formed by supplying the ligand solution 23 to the first QD containing layer to exchange at least a part of the ligand 25 contained in the first QD containing layer with the ligand 21. As described above, the EML 13b according to the present embodiment is formed by supplying the ligand solution 23 to the second QD containing layer to exchange at least a part of the ligand 25 contained in the second QD containing layer with the ligand 21.

As the solvent of the QD colloidal solutions containing the QDs 131a, the solvent of the QD colloidal solutions containing the QDs 131b, the solvent 22 of the ligand solution 23, the solvent as the rinse liquid, and the ligand 25, the solvents and the ligand 25 that are the same as those in the first embodiment are used. Specifically, for example, as described in the first embodiment, when the QDs 131 alone, the ligand 25 alone, and the QDs 131 and the ligand 25 in a state where the ligand 25 has coordinated to the QDs 131 are dissolved in a non-polar solvent, a non-polar solvent is used for the solvents of the QD colloidal solution containing the QDs 131a, the solvent of the QD colloidal solution containing the QDs 131b, and the rinse liquid, and a polar solvent is used for the solvent 22 of the ligand solution 23.

As described in the third modification of the first embodiment, when the ligand 25 is a monofunctional ligand including a polar bonding group and the QDs 131 and the ligand 25 in a state where the ligand 25 has coordinated to the QDs 131 are dissolved in a polar solvent, a polar solvent is used for the solvents of the QD colloidal solution containing the QDs 131a, the solvent of the QD colloidal solution containing the QDs 131b, and the rinse liquid, and a non-polar solvent is used for the solvent of the ligand solution.

In the present embodiment, the QDs 131a and the QDs 131b are not particularly limited as long as they are different QDs.

For example, the QDs 131a and the QDs 131b may be QDs that both have a core-shell structure but are different from each other in shell thicknesses. For example, when a QD having a relatively thick shell is used for the QDs 131b and a QD having a relatively thin shell is used for the QDs 131a, it is possible to obtain a light-emitting element that suppresses leakage of positive holes to the outside while ensuring injection efficiency of carriers, and has high luminous efficiency.

Further, in the light-emitting element according to the present embodiment, as long as the EML 13 has a structure in which a plurality of EMLs are layered and the ligand 21 is provided at the interface between the adjacent EMLs, the layered structure is not particularly limited.

For example, the EML 13 may have a multi-quantum well structure, and may include three or more layers of EMLs. In addition, as long as the EML 13 including a plurality of EMLs is provided between the anode electrode 11 and the cathode electrode 15, a layer other than the EML 13 does not necessarily need to be provided between the anode electrode 11 and the cathode electrode 15. The light-emitting element according to the present embodiment is an electroluminescent element that emits light when a voltage is applied to the EML 13, as in the case of the light-emitting elements according to the first to the third embodiments. The light-emitting element according to the present embodiment may also be used as, for example, a light source of a light-emitting device such as a display device or an illumination device, as in the case of the light-emitting elements according to the first to third embodiments.

When the light-emitting element includes the HTL 12, or the HIL 16 and the HTL 12, the positive hole transport material used for the HIL 16 and the HTL 12 needs not be nanoparticles, and may be, for example, an organic material as described above. Similarly, when the light-emitting element includes the ETL 14, or the EIL 17 and the ETL 14, the electron transport material used for the EIL 17 and the ETL 14 needs not be nanoparticles, and may be, for example, an organic material as described above.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
a first electrode;
a second electrode;
a first nanoparticle layer disposed between the first electrode and the second electrode and including first nanoparticles; and
a second nanoparticle layer disposed between the second electrode and the first nanoparticle layer and being in contact with the first nanoparticle layer, the second nanoparticle layer including second nanoparticles,
wherein an interface between the first nanoparticle layer and the second nanoparticle layer includes a ligand including a first coordinating functional group for coordination to the first nanoparticles and a second coordinating functional group for coordination to the second nanoparticles.

2. The light-emitting element according to claim 1,
wherein the ligand is at least one ligand selected from the group consisting of a ligand represented by general formula (1) below:
R¹—A¹—A²—(CH₂)ₙ—R² (1)
where R¹ represents one of the first coordinating functional group and the second coordinating functional group, R² represents another of the first coordinating functional group and the second coordinating functional group, A¹ represents a substituted or unsubstituted —((CH₂)ₘ₁—X¹)ₘ₂— group, A² represents direct bonding, an X² group, or a substituted or unsubstituted —((CH₂)ₘ₃—X²)ₘ₄— group, X¹ and X² represent polar bonding groups different from each other, n, m1, and m3 each independently represent an integer of from 1 to 4, and m2 and m4 each independently represent an integer of from 1 to 10, and
a ligand represented by general formula (2) below:
R³—Z—R⁴ (2)
where R³ represents one of the first coordinating functional group and the second coordinating functional group, R⁴ represents another of the first coordinating functional group and the second coordinating functional group, and Z represents a substituted or unsubstituted alkylene group having from 1 to 10 carbon atoms, or a substituted or unsubstituted unsaturated hydrocarbon group having from 2 to 10 carbon atoms.

3. The light-emitting element according to claim 2,
wherein A² is direct bonding, and
2≤m1×m2+n≤20 is satisfied.

4. The light-emitting element according to claim 3,
wherein 3≤m1×m2+n≤10 is satisfied.

5. The light-emitting element according to claim 2,
wherein A² is a —((CH₂)ₘ₃—X²)ₘ₄— group, and
2≤m1×m2+m3×m4+n≤20 is satisfied.

6. The light-emitting element according to claim 5,
wherein 3≤m1×m2+m3×m4+n≤10 is satisfied.

7. The light-emitting element according to claim 2,
wherein Z represents a substituted or unsubstituted alkylene group having from 4 to 10 carbon atoms, or a substituted or unsubstituted unsaturated hydrocarbon group having from 4 to 10 carbon atoms.

8. The light-emitting element according to claim 2,
wherein the polar bonding group is at least one polar bonding group selected from the group consisting of an ether bonding group, a sulfide bonding group, an imine bonding group, an ester bonding group, an amide bonding group, and a carbonyl group.

9. The light-emitting element according to claim 1,
wherein the first coordinating functional group and the second coordinating functional group are each independently a thiol group, an amino group, a carboxyl group, a phosphonic group, a phosphine group, or a phosphine oxide group.

10. The light-emitting element according to claim 1,
wherein the ligand is at least one ligand selected from the group consisting of 1,2-ethanedithiol, 1,2-propanedithiol, 1,3-propanedithiol, 1,2-butanedithiol, 1,3-butanedithiol, 1,4-butanedithiol, 2,3-butanedithiol, 1,6-hexanedithiol, 1,8-octanedithiol, 1,2-propanediamine, 1,3-propanediamine, 1,4-butanediamine, 3-amino-5-mercapto-1,2,4-triazole, 2-aminobenzenethiol, toluene-3,4-dithiol, dithioerythritol, dihydrolipoic acid, thiolactic acid, 3-mercaptopropionic acid, 1-amino-3,6,9,12,15,18-hexaoxahenicosan-21-oic acid, 2-[2-(2-aminoethoxy)ethoxy]acetic acid, 2,2′-(ethylenedioxy)diethanethiol, 2,2′-oxydiethanethiol, (12-phosphonododecyl)phosphonic acid, 11-mercaptoundecylphosphonic acid, 11-phosphonoundecanoic acid, and ethylene glycol bis(3-mercaptopropionate).

11. The light-emitting element according to claim 1,
wherein the first nanoparticles and the second nanoparticles each include a semiconductor material including Zn, and
the first coordinating functional group and the second coordinating functional group are each a thiol group.

12. The light-emitting element according to claim 1,
wherein the first nanoparticles are first quantum dots, and
the second nanoparticles are nanoparticles including a first carrier transport material.

13. The light-emitting element according to claim 1,
wherein the first nanoparticles are nanoparticles including a first carrier transport material, and
the second nanoparticles are nanoparticles including a second carrier transport material.

14. The light-emitting element according to claim 1,
wherein the first nanoparticles are first quantum dots, and
the second nanoparticles are second quantum dots.

15. The light-emitting element according to claim 12,
wherein the first carrier transport material is a semiconductor material including Zn atoms.

16. The light-emitting element according to claim 12,
wherein the first quantum dots include a semiconductor material including Zn in an outermost surface.

17. The light-emitting element according to claim 15,
wherein a number mean particle size of the nanoparticles including the first carrier transport material is in a range of from 1 to 15 nm.

18. (canceled)

19. (canceled)

20. The light-emitting element according to claim 15,
wherein the first electrode, the first nanoparticle layer, the second nanoparticle layer, and the second electrode are provided in this order from a lower layer side,
the first electrode is an anode electrode and the second electrode is a cathode electrode,
the first nanoparticle layer has a layer thickness in a range of from 1 to 150 nm, and
the second nanoparticle layer is thinner than the first nanoparticle layer.

21. The light-emitting element according to claim 15,
wherein the first electrode, the first nanoparticle layer, the second nanoparticle layer, and the second electrode are provided in this order from a lower layer side,
the first electrode is an anode electrode and the second electrode is a cathode electrode,
the first nanoparticle layer has a layer thickness in a range of from 1 to 150 nm, and
a density of the second nanoparticles in the second nanoparticle layer is lower than a density of the first nanoparticles in the first nanoparticle layer.

22. A manufacturing method for the light-emitting element according to claim 1, the manufacturing method comprising:
forming a first nanoparticle containing layer including the first nanoparticles, which is to be the first nanoparticle layer;
forming, on the first nanoparticle containing layer, a second nanoparticle containing layer including the second nanoparticles, which is to be the second nanoparticle layer; and
supplying, onto the second nanoparticle containing layer, a ligand solution including the ligand including the first coordinating functional group for coordination to the first nanoparticles and the second coordinating functional group for coordination to the second nanoparticles, after the formation of the second nanoparticle containing layer.

23. (canceled)

24. (canceled)
